(19) United States
(12) Patent Application Publication
(10) Pub. No.: US 2015/0060938 A1
(43) Pub. Date: Mar. 5, 2015

(54) SEMICONDUCTOR DEVICE AND SEMICONDUCTOR DEVICE MANUFACTURING METHOD

(71) Applicant: Fuji Electric Co., Ltd., Kawasaki-shi (JP)

(72) Inventor: Hong-fei LU, Matsumoto-city (JP)

(21) Appl. No.: 14/536,980

(22) Filed: Nov. 10, 2014

Related U.S. Application Data
(63) Continuation of application No. PCT/JP2012/073439, filed on Sep. 13, 2012.

(51) Int. Cl. H01L 29/739; H01L 29/66; H01L 21/306; H01L 21/265; H01L 21/324; H01L 21/304; H01L 29/06; H01L 29/36

(52) U.S. Cl. CPC H01L 29/7395; H01L 29/0619; H01L 29/66333; H01L 29/36; H01L 21/265; H01L 21/324; H01L 21/304; H01L 21/30604
USPC 257/139; 438/138

(57) ABSTRACT

An n⁻ type drift region, an n-type field stop region, and an n⁻ type FZ wafer are provided in an n⁻ type wafer. An edge termination structure portion is provided in a chip outer peripheral portion of regions of the n⁻ type wafer, surrounding an active region inside a chip inner portion. A thickness of the chip inner portion is less than a thickness of the chip outer peripheral portion owing to a groove. A p-type collector region is in contact with the n⁻ type FZ wafer and n-type field stop region. A collector electrode is in contact with the p-type collector region. A second distance between the collector electrode and the n-type field stop region in the edge termination structure portion is greater than a first distance between the collector electrode and the n-type field stop region in the active region.

### CROSS-REFERENCE TO RELATED APPLICATIONS

This application is a continuation of International Application No. PCT/JP2012/073439, filed on Sep. 13, 2012. The disclosure of the PCT application in its entirety, including the drawings, claims, and the specification thereof, is incorporated herein by reference.

### BACKGROUND

1. Field of the Invention

Embodiments of the present invention relate to a semiconductor device and a semiconductor device manufacturing method.

2. Discussion of the Background

High breakdown voltage discrete power devices play a central role in power conversion equipment. To date, for example, an insulated gate bipolar transistor (IGBT), an insulated gate field effect transistor having a metal-oxide-semiconductor structure (MOSFET: Metal Oxide Semiconductor Field Effect Transistor), and the like, are well known devices suitable as high breakdown voltage discrete power devices in such power conversion equipment.

IGBTs that can reduce on-state voltage owing to the occurrence of conductivity modulation are heavily used in high voltage power conversion equipment. Because of this, reducing IGBT conduction loss and switching loss is one important undertaking for reducing loss in power conversion equipment. A description will be given of a heretofore known IGBT, with a planar gate structure n-channel IGBT as an example. FIG. 26 is a cross sectional diagram showing a configuration of a heretofore known IGBT. FIG. 26 shows a state after a p⁺ type wafer used for fabricating (manufacturing) the heretofore known IGBT has been sawed into chips (the same also applies to FIGS. 27 and 28).

The heretofore known IGBT shown in FIG. 26 is such that an n-type buffer layer 103 and an n⁻ type drift region 102 are grown epitaxially in sequence on the front surface of a p⁺ type chip that forms a p⁺ type collector region 101. A p-type base region 104 is selectively provided in a surface layer on the side of the n⁻ type drift region 102 opposite to the p⁺ type collector region 101 side. An n⁺ type emitter region 105 is selectively provided inside the p-type base region 104. The n⁺ type emitter region 105 is exposed on the surface of portions of the p-type base region 104 not in contact with the n⁻ type drift region 102.

A gate electrode 108 is provided on a gate dielectric 107 across the surface of portions of the p-type base region 104 sandwiched by the n⁺ type emitter region 105 and the n⁻ type drift region 102. An emitter electrode 109 is in contact with the n⁺ type emitter region 105 and the p-type base region 104. The emitter electrode 109 is isolated from the gate electrode 108 by an interlayer dielectric omitted from the drawing. A collector electrode (not shown) is in contact with the back surface of the p⁺ type chip that forms the p⁺ type collector region 101.

In recent years, there has been progress in improvement of devices characteristics by thinning the wafer, and wafer thinning technology is also being applied to IGBTs. As a method of fabricating the heretofore known IGBT shown in FIG. 26, alone with applying wafer thinning technology, it is in the public domain that, instead of a p⁺ type wafer that forms the p⁺ type collector region 101, an n⁻ type wafer, made using a floating zone (FZ) method (hereafter referred to as an n⁻ type FZ wafer), that forms the n⁻ type drift region 102, is used.

Specifically, the following method is becoming mainstream as a method of manufacturing the heretofore known IGBT using wafer thinning technology. A description will be given of a method of manufacturing the heretofore known IGBT using wafer thinning technology, referring to FIG. 26. Firstly, a MOS gate (an insulated gate formed of metal-oxide-semiconductor) structure formed of the p-type base region 104, the n⁺ type emitter region 105, the gate dielectric 107, and the gate electrode 108 is formed on the front surface side of an n⁻ type FZ wafer that forms the n⁻ type drift region 102. Next, the thickness of the n⁻ type FZ wafer is reduced by grinding the back surface of the n⁻ type FZ wafer.

Next, the n-type buffer layer 103 and a p⁺ type collector region (a region corresponding to the p⁺ type collector region of FIG. 26, not shown) are formed in a surface layer of the ground back surface of the n⁻ type FZ wafer. Subsequently, by dicing the n⁻ type FZ wafer to form chips, the heretofore known IGBT with configuration shown in FIG. 26 is completed. By fabricating the IGBT using an n⁻ type FZ wafer that forms the n⁻ type drift region 102 in this way, the thickness of the p⁺ type collector region can be controlled thinner than 2 μm. In this case, the p⁺ type collector region does not function as a support body that maintains the mechanical strength of the IGBT.

Also, as a heretofore known IGBT, a reverse blocking IGBT (RB-IGBT) including an edge termination structure for securing reverse breakdown voltage is in the public domain An RB-IGBT has high reverse blocking characteristics with respect to reverse biased voltage applied to a p-n junction formed of a collector region and a drift region. A description will be given of a cross sectional structure of a heretofore known RB-IGBT. FIG. 27 is a cross sectional diagram showing a configuration of a heretofore known RB-IGBT.

The heretofore known RB-IGBT shown in FIG. 27 includes the p-type base region 104, the n⁺ type emitter region 105, the gate dielectric 107, the gate electrode 108, and the emitter electrode 109, in the same way as the heretofore known IGBT shown in FIG. 26, on the front surface of an n⁻ type chip that forms the n⁻ type drift region 102 in an active region. The active region is a region through which current flows when in an on-state. Reference signs 106, 110, and 113 are a p⁺ type base contact region, an n-type hole barrier region, and an interlayer dielectric, respectively.

An edge termination structure portion is provided on the outer side of the active region so as to surround the active region. The edge termination structure portion has a function of relaxing electrical field crowding at the pn junction at the peripheral of the active region, thus maintaining high breakdown voltage. A floating p-type region (field limiting ring: FLR) 114 is selectively provided in a surface layer of the front surface of the n⁻ type chip in the edge termination structure portion. A floating field plate (FP) 116 is in contact with the FLR 114 across a p⁺ type high concentration region provided inside the FLR 114.

A p-type collector region 111 is provided over the whole of the back surface of the n⁻ type chip. A collector electrode 112 is in contact with the p-type collector region 111. A p-type isolation region 121 is provided in an outer peripheral portion of the n⁻ type chip, surrounding the edge termination structure portion and reaching the p-type collector region 111 from the front surface of the n⁻ type chip. The p-type isolation region 121 has a function of securing reverse breakdown voltage. An FP 117 is in contact with the p-type isolation region 121 via a p⁺ type high concentration region provided inside the p-type isolation region 121. The FPs 116 and 117 are each isolated by an interlayer dielectric 113.

For this kind of heretofore known IGBT, it is effective in reducing conduction loss and switching loss through reducing the thickness of the n⁻ type drift region 102, that is, the thickness of the n⁻ type chip. Also, becoming mainstream in recent years is a field stop IGBT (hereafter referred to as an FS-IGBT) wherein the thickness of the n⁻ type drift region 102 is arranged to be the minimum thickness necessary for the required element breakdown voltage by optimizing the n-type impurity concentration of the n-type buffer layer 103 provided on the back surface side of the n⁻ type chip that forms the n⁻ type drift region 2.

A method whereby an n-type buffer layer is formed using a proton (H⁺) implantation and a thermal annealing process has been proposed as a method of forming an n-type buffer layer with an impurity concentration higher than that of an n⁻ type drift region in the n⁻ type drift region (for example, refer to U.S. Pat. No. 6,482,681 and Japanese Patent No. 4,128,777). It is commonly known that a predetermined region of a silicon (Si) wafer is doped to an n-type by a proton implantation and a low temperature annealing, for example, a disclosure was made on the relationship between the proton dose and induced donor concentration when carrying out a thermal annealing process for 30 minutes at a temperature of 350° C. (for example, refer to U.S. Pat. No. 6,482,681).

A description will be given of a cross sectional structure of a heretofore known IGBT shown in U.S. Pat. No. 6,482,681 and Japanese Patent No. 4,128,777, and of the impurity concentration in each region of the IGBT. FIG. 28 is a cross sectional diagram showing another configuration of a heretofore known IGBT. FIG. 29 is a characteristic diagram showing an impurity concentration distribution of the IGBT of FIG. 28. The heretofore known IGBT shown in FIG. 28 differs from the heretofore known IGBT shown in FIG. 26 in that an n⁻ type wafer that forms the n⁻ type drift region 102 is used instead of a low resistance p⁺ type wafer that forms a p⁺ type collector region, and the n-type buffer layer 103 and a p⁻ type collector region 131 are provided in a surface layer of the back surface of the n⁻ type wafer. That is, the heretofore known IGBT shown in FIG. 28 corresponds to the heretofore known IGBT shown in FIG. 26 fabricated by applying wafer thinning technology.

In U.S. Pat. No. 6,482,681 and Japanese Patent No. 4,128,777, the n-type buffer layer 103 is formed by a single or multiple proton implantations into the ground back surface of the n⁻ type wafer being carried out at an acceleration energy of 500 keV or more, after which a thermal annealing process is carried out for 30 minutes to 60 minutes at a temperature of in the region of 300° C. to 400° C. By the proton implantation and the thermal annealing being carried out in this way, the n-type impurity concentration of a predetermined region in the n⁻ type drift region 102 increases, whereby the n-type buffer layer 103 is formed, as shown in FIG. 29. The proton dose and thermal annealing conditions necessary for forming the n-type buffer layer 103 are disclosed in, for example, D. Silber et al., “Improved Dynamic Properties of GTO-Thyristors and Diodes by Proton Implantation” (IEEE International Electron Device Meeting, Technical Digest: IEDM '85), (U.S.A.), 1985, Volume 31, pages 162 to 165.

The limit value of the wafer thickness (hereafter referred to as the limit thickness) when thinning the wafer, although also depending on the manufacturing device and the manufacturing method, is in the region of 80 μm for silicon when considering manufacturability. The reason for this is that when reducing the wafer thickness to 80 μm or less, mechanical strength decreases, and yield decreases markedly. As the device breakdown voltage depends on the thickness of the n⁻ type drift region 102, the lower the breakdown voltage, the lower the ideal value of the design thickness of the n⁻ type drift region 102 (approximately 10 μm with respect to a breakdown voltage of 100V, hereafter referred to as the ideal thickness) required to realize the required breakdown voltage. However, as it is not possible when considering manufacturability for the wafer thickness to be the limit thickness or lower, the thickness of the n⁻ type drift region 102 of an IGBT of a breakdown voltage class of 600V or less is generally 60 μm or more, which is the ideal thickness. Because of this, considerable room is left for performance improvement by further wafer thinning in an IGBT of a breakdown voltage class of 600V or less.

IGBTs of a breakdown voltage class of 600V or less are used in, for example, the following various kinds of application. IGBTs of a breakdown voltage class of 400V are widely used in pulse power supplies of plasma display panels (PDP), strobes, and the like. Also, when the input voltage of a power conversion equipment is 220V (AC: alternating current), the DC (direct current) link voltage after rectification is 300V, because of which an IGBT of a breakdown voltage class of 600V is used as a main switch device in an inverter unit of the power conversion equipment.

Furthermore, an IGBT of a breakdown voltage class of 400V is used as a switching element or a main element configuring an inverter unit. Specifically, it is commonly known that the power conversion efficiency of a power conversion equipment can be increased by changing the output voltage level control of the inverter unit in the power conversion equipment from a heretofore known two-level control to a three-level control (for example, refer to A. Nabae et al., “A New Neutral-Point-Clamped PWM Inverter”, (IEEE Transactions on Industry Applications), 1981, Volume 1A to Volume 17, Issue 5, pages 518 to 523 (FIG. 10)). When changing the output voltage level control of the inverter unit in the power conversion equipment to a three-level control, an IGBT of a breakdown voltage class of 400V is used as an intermediate switching element of a three-level conversion unit that converts the output voltage of the inverter unit to three levels. Also, it has also been proposed that an RB-IGBT of a breakdown voltage class of 400V, including a function the same as when connecting a heretofore known IGBT and a diode in series, is used as an intermediate switching element of a three-level conversion unit (for example, refer to M. Yatsu et al., “A Study of High Efficiency UPS Using Advanced Three-level Topology”, (Preliminary Conference Program PCIM Europe 2010), (Nuremburg), May, 2010, pages 550 to 555 (FIG. 1)).

Also, in an electric vehicle (EV), power is supplied through a power conversion equipment from a drive battery to a motor, which is dynamic power source, because of which importance is placed on improving the power conversion efficiency of the power conversion equipment. For example, when the power supplied from the drive battery to the motor is 80 kW or less, it is appropriate that the DC link voltage of the power conversion equipment is in the region of 100V to 250V, because of which an IGBT of a breakdown voltage class of 400V is used as a main switch device of an inverter unit in the power conversion equipment

An IGBT of a breakdown voltage class of 400V used in various applications in this way is such that the ideal thickness of the n⁻ type drift region 102 is in the region of 40 μm, which is less than the wafer limit thickness realizable when considering manufacturability. Consequently, when fabricating an IGBT of a breakdown voltage class of 400V, reducing the thickness of the n⁻ type drift region 102 to in the region of 40 μm, which is the ideal thickness, leads to a decrease in the mechanical strength of the wafer.

A method whereby an outer peripheral portion of the wafer is left thick to a predetermined width (hereafter referred to as a rib portion), and only a central portion of the wafer back surface is thinned, has been proposed as a method of securing the mechanical strength of a thin wafer (for example, refer to DISCO Co., Ltd., “TAIKO Process”, (online), 2001 to 2012, Internet, (Aug. 3, 2012 search), (URL: http://www.disco.co.jp/jp/solution/library/taiko.html) (“TAIKO Process”) and JP-A-2007-335659). A description will be given of the technology of TAIKO Process. FIGS. 30 and 31 are cross sectional diagrams showing a wafer section partway through the manufacturing of a heretofore known semiconductor device. Firstly, a front surface element structure 201 of a MOS gate structure, an FLR, an FP, and the like, is formed on the front surface side of a wafer 200, after which the front surface is covered with a protective resist film 211, as shown in FIG. 30.

Next, a back grinding (BG) tape 212 is attached to the front surface of the wafer 200 covered with the protective resist film 211. Next, only a central portion 200-2 of the wafer 200 back surface is ground so that a rib portion 200-1 remains in an outer peripheral portion of the wafer 200, as shown in FIG. 31. By the rib portion 200-1 being left in the wafer 200 outer peripheral portion, the concentration of stress in the outer peripheral portion of the wafer 200 is reduced compared with when uniformly grinding the whole back surface of the wafer 200, whereby the mechanical strength of the wafer 200 increases. Because of this, warping of the wafer 200 is reduced, and chipping, cracking, and the like, are reduced.

Also, a description will be given of the technology of JP-A-2007-335659. FIG. 32 is a sectional view showing a wafer section partway through the manufacturing of a heretofore known semiconductor device. Firstly, an oxide film 221, which is an etching resistant protective film, is formed on the front surface and back surface of the wafer 200, on which a front surface side element structure portion has been fabricated, as shown in FIG. 32. Next, a resist mask 222 that covers the oxide film 221 to a predetermined width inward from the wafer 200 outer peripheral end portion is formed on the back surface of the wafer 200. Next, with the resist mask 222 as a mask, the oxide film 221 formed on the back surface of the wafer 200 is removed, leaving the predetermined width from the outer peripheral end portion of the wafer 200. Then, the back surface of the wafer 200 is etched to a predetermined depth, after which the oxide film 221 remaining on the front surface and outer peripheral end portion of the back surface of the wafer 200 is removed.

Also, the following method has been proposed as another method of securing the mechanical strength of a thin wafer. The mechanical strength necessary when processing a semiconductor element that causes a main current to flow between first and second electrodes inside a semiconductor wafer so as to exit onto mutually opposing first and second main surfaces of the semiconductor wafer is secured by the thickness of the semiconductor wafer on which the element is made. Before making the element, a thin region portion is formed by providing a depressed portion in one main surface of the semiconductor wafer, and the semiconductor element is made therein (for example, refer to JP-A-2002-016266).

Also, a device wherein a semiconductor substrate includes in a central portion on one main surface side a semiconductor layer, having at least the thickness necessary for the breakdown voltage, formed of silicon carbide or gallium nitride, and has on the other main surface side a depressed portion in a position opposing the central portion and a support portion surrounding a bottom portion of the depressed portion and forming a side surface of the depressed portion, is formed so that the mechanical strength is secured (for example, refer to JP-A-2007-243080). In JP-A-2007-243080, the depressed portion is formed by dry etching or the like.

However, the heretofore known technology shown in FIGS. 30 to 32 is such that the wafer 200 is reinforced only in the rib portion 200-1 of the external peripheral portion of the wafer 200. Because of this, the more the central portion 200-2 of the wafer 200 is thinned in order for the thickness of the n⁻ type drift region 102 to be the ideal thickness, and the larger the diameter of the wafer 200, the more markedly the mechanical strength of the wafer 200 decreases, and a problem occurs in that the wafer 200 cracks easily. Consequently, it is not possible for the thickness of the wafer 200 to be reduced below 80 μm, which is the limit thickness at which no problem occurs in terms of manufacturability, and thus not possible to fabricate a low breakdown voltage IGBT of a breakdown voltage class of 600V or less under ideal design conditions.

Also, the heretofore known technology shown in FIGS. 30 to 32 is such that, during an electrical characteristic test carried out on the wafer 200 before dicing the wafer 200 to form chips, the collector electrode and the like on the wafer 200 back surface come into contact with a support stand on which the wafer 200 is mounted. Because of this, the heretofore known IGBT is such that there is concern that the p-type collector region 111 and the n-type buffer layer 103 will be damaged by extraneous matter (particles) or friction occurring on the back surface of the wafer 200, and that the voltage will drop and the leakage current will increase. Also, the heretofore known RB-IGBT is such that there is concern that the p-type collector region 111 will be damaged by extraneous matter or friction occurring on the back surface of the wafer 200, and that the reverse breakdown voltage characteristics will deteriorate or the reverse breakdown voltage characteristics will become unobtainable.

### SUMMARY

Embodiments of the invention provide a semiconductor device and a semiconductor device manufacturing method such that the mechanical strength is high. Embodiments of the invention also provide a semiconductor device and a semiconductor device manufacturing method that may have optimum electrical characteristics obtainable from the design.

A semiconductor device according to one aspect of the invention has the following characteristics. A first conductivity type chip is formed of a first conductivity type first semiconductor region, a first conductivity type second semiconductor region, and a first conductivity type third semiconductor region provided between the first conductivity type first semiconductor region and the first conductivity type second semiconductor region and having resistivity lower than that of the first conductivity type second semiconductor region. A groove penetrating the first conductivity type first semiconductor region and reaching the first conductivity type third semiconductor region is provided. An active region is provided inside an inner portion, the thickness of which is less than that of an outer peripheral portion of the first conductivity type chip owing to the groove. An edge termination structure portion that maintains breakdown voltage is provided in the peripheral portion of the first conductivity type chip. A second conductivity type semiconductor region in contact with the first conductivity type third semiconductor region and the first conductivity type first semiconductor region is provided. An output electrode in contact with the second conductivity type semiconductor region is provided. The distance in the first conductivity type chip thickness direction between the output electrode and the first conductivity type third semiconductor region is greater in the edge termination structure portion than in the active region.

Also, a semiconductor device according to one aspect of the invention has the following characteristics. A first conductivity type chip is formed of a first conductivity type first semiconductor region, a first conductivity type second semiconductor region, and a first conductivity type third semiconductor region provided between the first conductivity type first semiconductor region and the first conductivity type second semiconductor region and having resistivity lower than that of the first conductivity type second semiconductor region. A groove is provided to a depth less than the thickness of the first conductivity type first semiconductor region from the first conductivity type first semiconductor region side surface of the first conductivity type chip. An active region is provided inside an inner portion, the thickness of which is less than that of an outer peripheral portion of the first conductivity type chip owing to the groove. An edge termination structure portion that maintains breakdown voltage is provided in the peripheral portion of the first conductivity type chip. A second conductivity type semiconductor region in contact with the first conductivity type third semiconductor region and the first conductivity type first semiconductor region is provided. An output electrode in contact with the second conductivity type semiconductor region is provided. The distance in the first conductivity type chip thickness direction between the second conductivity type semiconductor region and the first conductivity type third semiconductor region is greater in the edge termination structure portion than in the active region.

Also, the semiconductor device according to the aspect of the invention is characterized in that the thickness of the first conductivity type third semiconductor region is 1.5 μm or more, 10 μm or less.

Also, the semiconductor device according to the aspect of the invention is characterized in that the average impurity concentration of the first conductivity type third semiconductor region is 3.0×10¹⁵ cm⁻³ to 2.0×10¹⁶ cm⁻³.

Also, the semiconductor device according to the aspect of the invention is characterized in that the first conductivity type second semiconductor region is an epitaxial growth layer on the first conductivity type third semiconductor region.

Also, the semiconductor device according to the aspect of the invention is characterized in that the first conductivity type third semiconductor region is a region formed by protons introduced into the first conductivity type chip being transformed into donors.

Also, the semiconductor device according to the aspect of the invention is characterized in that the resistivity of the first conductivity type second semiconductor region is equal to the resistivity of the first conductivity type first semiconductor region.

Also, the semiconductor device according to the aspect of the invention is characterized in that the thickness of the outer peripheral portion of the first conductivity type chip is greater than 80 μm.

A semiconductor device manufacturing method according to one aspect of the invention, being a method of manufacturing a semiconductor device including an edge termination structure portion that maintains breakdown voltage provided in a peripheral portion of a first conductivity type chip and an active region provided inside an inner portion, the thickness of which is less than that of the outer peripheral portion of the first conductivity type chip, has the following characteristics. Firstly, a first step of forming a first conductivity type semiconductor region having resistivity lower than that of a first conductivity type wafer at a predetermined depth in the first conductivity type wafer is carried out. Next, a second step of forming a groove reaching the first conductivity type semiconductor region from the back surface of the first conductivity type wafer, whereby the thickness of an inner portion of a region forming the first conductivity type chip is less than the thickness of an outer peripheral portion, is carried out. Next, a third step of forming a second conductivity type semiconductor region along the back surface of the first conductivity type wafer and side walls of the groove is carried out. Next, a fourth step of forming an output electrode on the second conductivity type semiconductor region so that the distance in the first conductivity type wafer thickness direction from the first conductivity type semiconductor region is greater in the edge termination structure portion than in the active region is carried out.

A semiconductor device manufacturing method according to one aspect of the invention, being a method of manufacturing a semiconductor device including an edge termination structure portion that maintains breakdown voltage provided in a peripheral portion of a first conductivity type chip and an active region provided inside an inner portion, the thickness of which is less than that of the outer peripheral portion of the first conductivity type chip, has the following characteristics. Firstly, a first step of forming a first conductivity type semiconductor region having resistivity lower than that of a first conductivity type wafer at a predetermined depth in the first conductivity type wafer is carried out. Next, a second step of forming a groove from the back surface of the first conductivity type wafer to a depth less than the thickness in the first conductivity type wafer depth direction from the back surface of the first conductivity type wafer to the first conductivity type semiconductor region, whereby the thickness of an inner portion of a region forming the first conductivity type chip is less than the thickness of an outer peripheral portion, is carried out. Next, a third step of forming a second conductivity type semiconductor region along the back surface of the first conductivity type wafer and side walls of the groove so that the distance in the first conductivity type wafer thickness direction to the first conductivity type semiconductor region is greater in the edge termination structure portion than in the active region is carried out. Next, a fourth step of forming an output electrode on the second conductivity type semiconductor region is carried out.

Also, the semiconductor device manufacturing method according to the aspect of the invention is characterized in that, in the first step, the first conductivity type wafer is formed by a first formation step of forming the first conductivity type semiconductor region, having resistivity lower than that of a first conductivity type support wafer, on the front surface of the first conductivity type support wafer, and a second formation step of depositing a first conductivity type epitaxial growth layer having resistivity higher than that of the first conductivity type semiconductor region on the first conductivity type semiconductor region.

Also, the semiconductor device manufacturing method according to the aspect of the invention is such that in the first step, firstly, a first implantation step of implanting protons from the back surface of the first conductivity type wafer is carried out. Next, the semiconductor device manufacturing method according to the aspect of the invention is characterized in that, at a predetermined timing after the first implantation step, a first thermal annealing step of activating the protons implanted into the first conductivity type wafer using thermal annealing, thereby forming the first conductivity type semiconductor region at a predetermined depth in the first conductivity type wafer, is carried out.

Also, the semiconductor device manufacturing method according to the aspect of the invention is characterized by further including a thinning step of reducing the thickness of the first conductivity type wafer by grinding the back surface of the first conductivity type wafer before the first implantation step. Further, the semiconductor device manufacturing method according to the aspect of the invention is characterized in that protons are implanted in the first implantation step, with acceleration energy in a range of 1.6 MeV to 2.5 MeV, so that the total dose of the first conductivity type semiconductor region is in a range of 5.0×10¹³ cm⁻² to 5.0×10¹⁴ cm⁻².

Also, the semiconductor device manufacturing method according to the aspect of the invention is characterized by further including a thinning step of reducing the thickness of the first conductivity type wafer by grinding the back surface of the first conductivity type wafer after the first implantation step. Further, the semiconductor device manufacturing method according to the aspect of the invention is characterized in that protons are implanted in the first implantation step, with acceleration energy in a range of 7.0 MeV to 8.0 MeV, so that the total dose of the first conductivity type semiconductor region is in a range of 5.0×10¹³ cm⁻² to 5.0×10¹⁴ cm⁻².

Also, the semiconductor device manufacturing method according to the aspect of the invention is characterized in that, in the second step, the groove is formed by wet etching.

According to embodiments of the invention, it is possible to disperse the concentration of stress on the wafer by the thickness of the chip outer peripheral portion being left greater than the thickness of the chip inner portion in each region on the wafer that forms a chip. Also, by the thickness of the chip outer peripheral portion being left greater than the thickness of the chip inner portion, and the distance in the chip thickness direction between the collector electrode and a field stop region being greater in most of the edge termination structure portion than in the active region, it is possible to reduce the amount of carriers injected from the collector region in the edge termination structure portion compared with a semiconductor device wherein the chip thickness is uniform from the edge termination structure portion to the active region. Because of this, the possibility of the edge termination structure portion being destroyed when a large current is turned off is markedly reduced, and the reverse biased safe operating area (RBSOA) of the element becomes easier to maintain.

Also, according to embodiments of the invention, by a groove being formed in the back surface of the wafer, leaving the thickness of the chip outer peripheral portion greater than the thickness of the chip inner portion in each region that forms a chip, it is possible to reduce the chip thickness in the active region compared with that in a heretofore known rib wafer wherein only the wafer outer peripheral portion is left thicker than the wafer central portion. Also, by a deep groove reaching the field stop region being formed from the back surface of the wafer, it is possible to further reduce the thickness of the chip inner portion. Because of this, when fabricating a low breakdown voltage IGBT of a breakdown voltage class of, for example, 600V or less, it is possible for the thickness of the drift region to be the ideal thickness demanded by the design in order to realize the required breakdown voltage.

Also, according to embodiments of the invention, by the thickness of the chip outer peripheral portion being left greater than the thickness of the chip inner portion in each region that forms a chip, the collector region, the collector electrode, and the like, provided in the active region do not come into contact with a support stand on which the wafer is mounted during, for example, an electrical characteristic test carried out on the wafer before dicing. Because of this, it is possible to prevent the occurrence of a problem wherein the collector region or the field stop region is damaged, and the voltage drops and leakage current increases, and of a problem wherein the collector region is damaged, and the reverse breakdown voltage characteristics degrade or the reverse breakdown voltage characteristics become unobtainable.

According to the semiconductor device and semiconductor device manufacturing method according to embodiments of the invention, an advantage is obtained in that it is possible to increase the mechanical strength. Also, according to the semiconductor device and semiconductor device manufacturing method according to embodiments of the invention, an advantage is obtained in that it is possible to provide a semiconductor device and semiconductor device manufacturing method having optimum electrical characteristics.

### BRIEF DESCRIPTION OF DRAWINGS

FIG. 1 is a cross sectional diagram showing a configuration of a semiconductor device according to Embodiment 1.

FIG. 2 is a cross sectional diagram showing a state partway through the manufacture of the semiconductor device according to Embodiment 1.

FIG. 3 is a cross sectional diagram showing a state partway through the manufacture of the semiconductor device according to Embodiment 1.

FIG. 4 is a cross sectional diagram showing a state partway through the manufacture of the semiconductor device according to Embodiment 1.

FIG. 5 is a cross sectional diagram showing a state partway through the manufacture of the semiconductor device according to Embodiment 1.

FIG. 6 is a cross sectional diagram showing a state partway through the manufacture of the semiconductor device according to Embodiment 1.

FIG. 7 is a cross sectional diagram showing a state partway through the manufacture of the semiconductor device according to Embodiment 1.

FIG. 8 is a cross sectional diagram showing a state partway through the manufacture of the semiconductor device according to Embodiment 1.

FIG. 9 is a cross sectional diagram showing a state partway through the manufacture of the semiconductor device according to Embodiment 1.

FIG. 10 is a cross sectional diagram showing a state partway through the manufacture of the semiconductor device according to Embodiment 1.

FIG. 11 is a cross sectional diagram showing a state partway through the manufacture of the semiconductor device according to Embodiment 1.

FIG. 12 is a cross sectional diagram showing a configuration of a semiconductor device according to Embodiment 2.

FIG. 13 is a cross sectional diagram showing a state partway through the manufacture of the semiconductor device according to Embodiment 2.

FIG. 14 is a cross sectional diagram showing a state partway through the manufacture of the semiconductor device according to Embodiment 2.

FIG. 15 is a cross sectional diagram showing a state partway through the manufacture of a semiconductor device according to Embodiment 3.

FIG. 16 is a cross sectional diagram showing a state partway through the manufacture of the semiconductor device according to Embodiment 3.

FIG. 17 is a cross sectional diagram showing a state partway through the manufacture of a semiconductor device according to Embodiment 4.

FIG. 18 is a cross sectional diagram showing a state partway through the manufacture of the semiconductor device according to Embodiment 4.

FIG. 19 is a cross sectional diagram showing a state partway through the manufacture of the semiconductor device according to Embodiment 4.

FIG. 20 is a cross sectional diagram showing a state partway through the manufacture of the semiconductor device according to Embodiment 4.

FIG. 21 is a cross sectional diagram showing a state partway through the manufacture of the semiconductor device according to Embodiment 4.

FIG. 22 is a cross sectional diagram showing a state partway through the manufacture of a semiconductor device according to Embodiment 5.

FIG. 23 is a cross sectional diagram showing a state partway through the manufacture of the semiconductor device according to Embodiment 5.

FIG. 24 is a cross sectional diagram showing a state partway through the manufacture of the semiconductor device according to Embodiment 5.

FIG. 25 is a cross sectional diagram showing a state partway through the manufacture of the semiconductor device according to Embodiment 5.

FIG. 26 is a cross sectional diagram showing a configuration of a heretofore known IGBT.

FIG. 27 is a cross sectional diagram showing a configuration of a heretofore known RB-IGBT.

FIG. 28 is a cross sectional diagram showing another configuration of a heretofore known IGBT.

FIG. 29 is a characteristic diagram showing an impurity concentration distribution of the IGBT of FIG. 28.

FIG. 30 is a cross sectional diagram showing a wafer section partway through the manufacture of a heretofore known semiconductor device.

FIG. 31 is a cross sectional diagram showing a wafer section partway through the manufacture of a heretofore known semiconductor device.

FIG. 32 is a cross sectional diagram showing a wafer section partway through the manufacture of a heretofore known semiconductor device.

### DETAILED DESCRIPTION OF ILLUSTRATED EMBODIMENTS

Hereafter, referring to the attached drawings, a detailed description will be given of embodiments of a semiconductor device and a semiconductor device manufacturing method according to the invention. A layer or region being prefixed by n or p in the description and attached drawings means that electrons or holes respectively are majority carriers. Also, + or − attached to n or p means a higher impurity concentration or lower impurity concentration respectively than in a layer or a region to which neither is attached. The same reference signs are given to the same configurations in the following description of the embodiments and in the attached drawings, and redundant descriptions are omitted.

### Embodiment 1

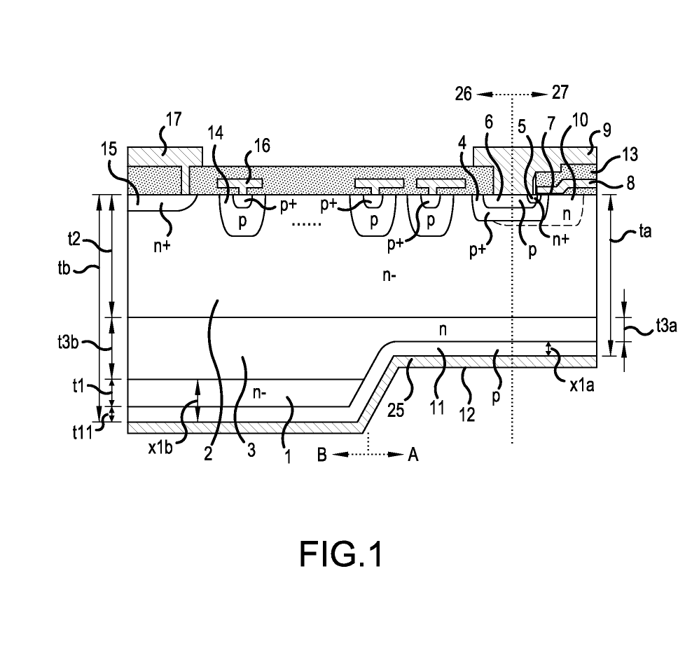

A description will be given of a configuration of a semiconductor device according to Embodiment 1, with a planar gate structure field stop IGBT (FS-IGBT) shown in FIG. 1 as an example. FIG. 1 is a cross sectional diagram showing a configuration of the semiconductor device according to Embodiment 1. As shown in FIG. 1, the semiconductor device according to Embodiment 1 includes, on an n⁻ type wafer, an edge termination structure portion 26 that relaxes an electrical field exerted on an n⁻ type drift region 2, thus maintaining breakdown voltage, and an active region 27 through which current flows when the semiconductor device is in an on-state.

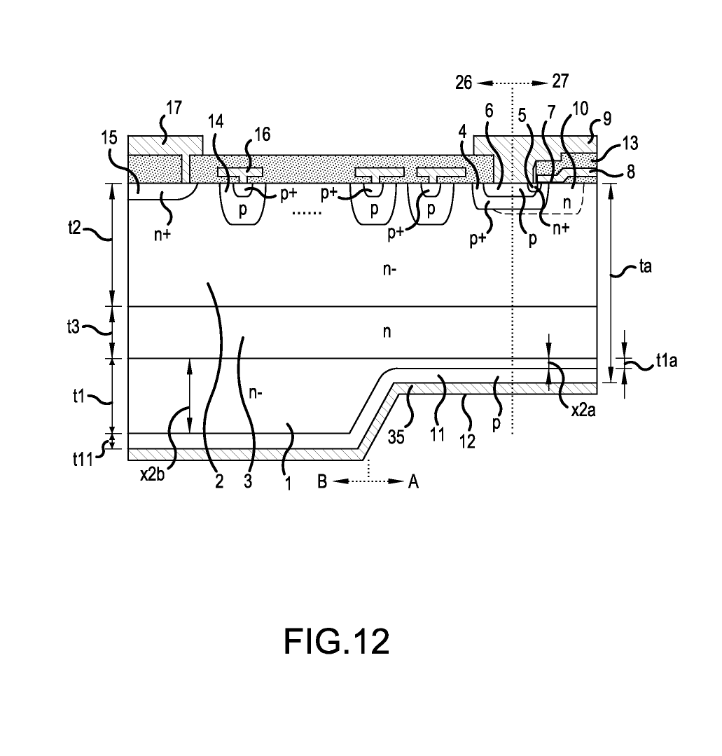

The n⁻ type wafer is formed by, for example, an n⁻ type FZ wafer (first first conductivity type semiconductor region) 1, an n-type field stop region (third first conductivity type semiconductor region) 3, and an n⁻ type drift region (second first conductivity type semiconductor region) 2 being deposited sequentially from the back surface side. FIG. 1 shows a sectional structure from one portion of the active region 27 to a chip outer peripheral portion after the n⁻ type wafer is diced to form chips (the same also applies to FIG. 12). The n-type field stop region 3 is provided from the active region 27 to the edge termination structure portion 26 between the n⁻ type FZ wafer 1 and the n⁻ type drift region 2. The average impurity concentration of the n-type field stop region 3 may be 3.0×10¹⁵ cm⁻³ to 2.0×10¹⁶ cm⁻³.

The active region 27 is provided inside a chip inner portion A, inward of a chip outer peripheral portion B and of a thickness less than that of the chip outer peripheral portion B. The edge termination structure portion 26 is provided on the outer side of the active region 27, surrounding the active region 27. The edge termination structure portion 26 may be provided from the chip outer peripheral portion B to the chip inner portion A of a thickness less than that of the chip outer peripheral portion B, or may be provided only in the chip outer peripheral portion B. A groove 25 penetrating the n⁻ type FZ wafer 1 from the n⁻ type chip back surface and reaching the n-type field stop region 3 is provided in the back surface of the n⁻ type chip (the back surface of the n⁻ type FZ wafer 1). Because of the groove 25, the n⁻ type FZ wafer 1 is not provided in the chip inner portion A.

A thickness to of the chip inner portion A is a thickness that is the sum of a thickness t2 of the n⁻ type drift region 2, a thickness t3a of the n-type field stop region 3 in the chip inner portion A, and a thickness t11 of a p-type collector region (second conductivity type semiconductor region) 11, to be described hereafter, and is less than a thickness tb of the chip outer peripheral portion B. The thickness t3a of the n-type field stop region 3 in the chip inner portion A may be, for example, 1.5 μm to 10.0 μm. This is because the n-type field stop region 3 is of 1.5 μm to 3.0 μm when using arsenic or antimony for the formation of the n-type field stop region 3, but the n-type field stop region 3 is of 1.5 μm to 8.0 μm when using phosphorus. The thickness tb of the chip outer peripheral portion B is a thickness that is the sum of the thickness t2 of the n⁻ type drift region 2, a thickness t3b of the n-type field stop region 3 in the chip outer peripheral portion B, a thickness t1 of the n⁻ type FZ wafer 1, and the thickness t11 of the p-type collector region 11, to be described hereafter.

The thickness tb of the chip outer peripheral portion B may be, for example, greater than 80 μm. The reason for this is that it is thus possible to function as a support body that maintains the mechanical strength of the FS-IGBT. The depth of the groove 25 may be greater than the thickness t1 of the n⁻ type FZ wafer 1. Provided that the thickness t3a of the n-type field stop region 3 in the chip inner portion A is maintained at a thickness of 1.5 μm to 10.0 μm, the thickness t3a may be less than the thickness t3b of the n-type field stop region 3 in the chip outer peripheral portion B.

Also, because of the groove 25, the n-type field stop region 3 is exposed in the chip inner portion A, and the n⁻ type FZ wafer 1 is exposed in the chip outer peripheral portion B, on the back surface of the n⁻ type chip. The p-type collector region 11 is provided over the whole n⁻ type chip back surface so as to come into contact with the n-type field stop region 3 and n⁻ type FZ wafer 1 exposed on the back surface of the n⁻ type chip. A collector electrode (output electrode) 12 is in contact with the p-type collector region 11.

A second distance x1b in the chip thickness direction between the collector electrode 12 and n-type field stop region 3 in the chip outer peripheral portion B is greater than a first distance x1a in the chip thickness direction between the collector electrode 12 and n-type field stop region 3 in the chip inner portion A. Because of this, it is possible to reduce the amount of carriers injected from the p-type collector region 11 into the n⁻ type drift region 2 in the edge termination structure portion 26 in an off-state. The first distance x1a is the thickness t11 of the p-type collector region 11. The second distance x1b is the sum of the thickness t1 of the n⁻ type FZ wafer 1 and the thickness t11 of the p-type collector region 11.

The chip outer peripheral portion B is provided from the edge termination structure portion 26 to a dicing line (not shown) on the outer periphery of the chip. That is, a front surface element structure of the semiconductor device according to Embodiment 1 is provided across from the chip inner portion A to the chip outer peripheral portion B. The front surface element structure is an element structure of the FS-IGBT provided on the front surface (the n⁻ type drift region 2 side surface) of the n⁻ type chip in the active region 27 and an edge termination structure of the FS-IGBT provided on the front surface of the n⁻ type chip in the edge termination structure portion 26.

An FS-IGBT element structure formed of a MOS gate structure, an emitter electrode 9, and the like, is provided on the front surface of the n⁻ type chip in the active region 27. A MOS gate structure is formed of a p-type base region 4, an n⁺ type emitter region 5, a p⁺ type base contact region 6, an n-type hole barrier region 10, a gate dielectric 7, and a gate electrode 8. A single cell of the active region 27 is configured of the MOS gate structure, the emitter electrode 9, the n⁻ type drift region 2, an n-type field stop region 3, a p-type collector region 11, and a collector electrode 12.

Specifically, the p-type base region 4 and the n-type hole barrier region 10 are selectively provided in a surface layer on the n⁻ type chip front surface side (the n⁻ type drift region 2 side surface side). The n-type hole barrier region 10 is in contact with the p-type base region 4, covering the n-type field stop region 3 side of the p-type base region 4. The n⁺ type emitter region 5 and the p⁺ type base contact region 6 are selectively provided inside the p-type base region 4. The n⁺ type emitter region 5 and the p⁺ type base contact region 6 are exposed on the front surface of the n⁻ type chip.

The p⁺ type base contact region 6 is in contact with the n⁺ type emitter region 5, covering the n-type field stop region 3 side of the n⁺ type emitter region 5. The gate electrode 8 is provided across the gate dielectric 7 on the surface of a portion of the p-type base region 4 sandwiched by the n⁻ type drift region 2 and the n⁺ type emitter region 5. The emitter electrode 9 is in contact with the p-type base region 4 and the n⁺ type emitter region 5 on the front surface side of the n⁻ type chip, short circuiting the p-type base region 4 and n⁺ type emitter region 5. The emitter electrode 9 is electrically isolated from the gate electrode 8 by an interlayer dielectric 13.

An edge termination structure for an FS-IGBT is provided on the front surface of the n⁻ type chip in the edge termination structure portion 26, which is formed of a floating p-type region (field limiting ring: FLR) 14, the n⁺ type region 15, and floating field plates (FP) 16 and 17. Specifically, a plurality of the FLR 14 and the n⁺ type region 15 are selectively provided in a surface layer on the front surface side (the n⁻ type drift region 2 side) of the n⁻ type chip.

The n⁺ type region 15 is provided in a chip outer peripheral termination portion, separated from the FLR 14. A plurality of the FP 16 is provided on the front surface of the n⁻ type chip. Each FP 16 is in contact with the FLR 14 via a p⁺ type high concentration region provided inside the FLR 14. Also, the FP 17, which is in contact with the n⁺ type region 15, is provided on the front surface of the n⁻ type chip. The FPs 16 and 17 are each isolated by the interlayer dielectric 13.

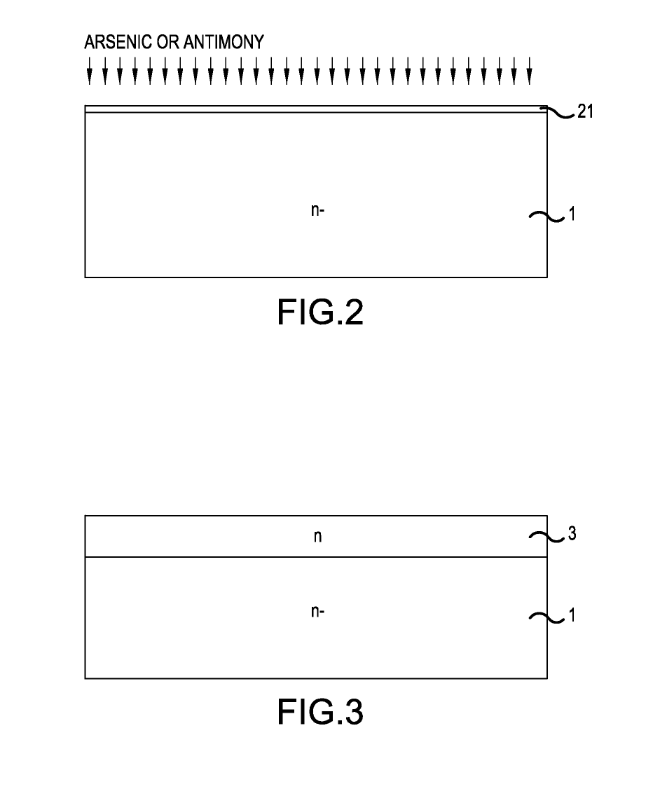

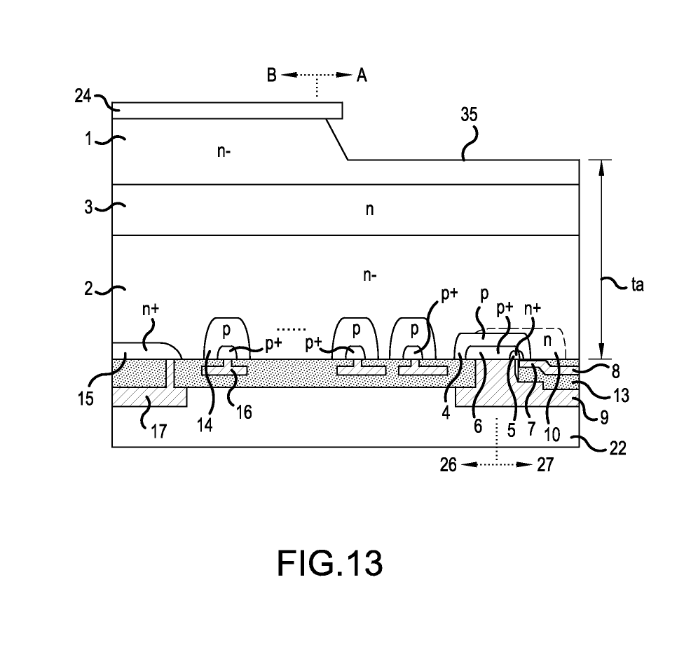

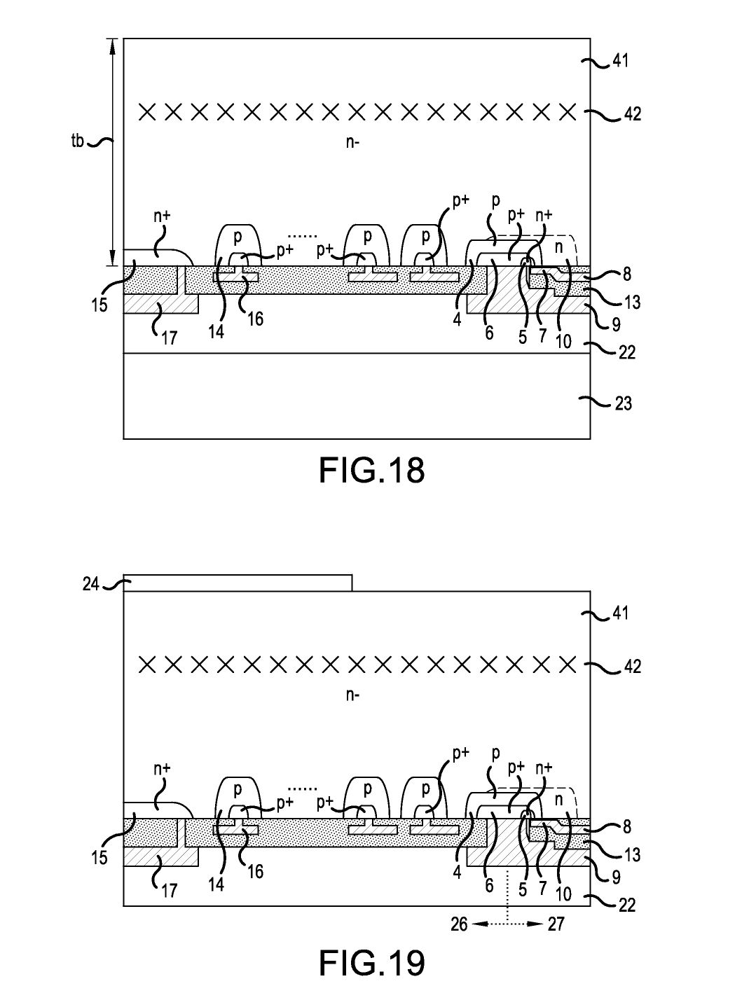

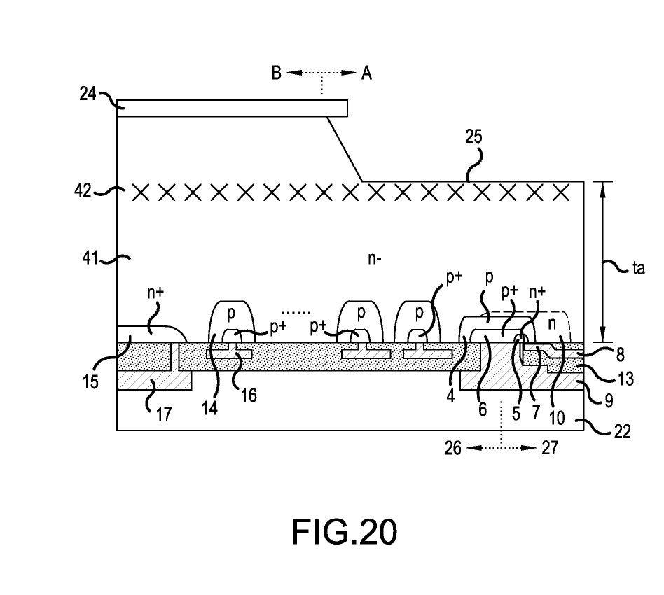

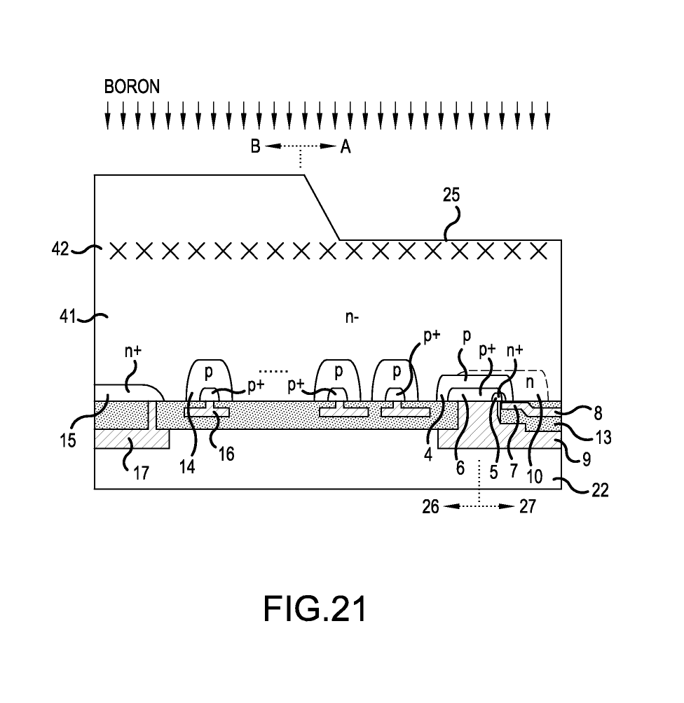

Next, a description will be given of a method of manufacturing the semiconductor device according to Embodiment 1, with a case of fabricating, for example, a 400V breakdown voltage class FS-IGBT as an example. FIGS. 2 to 11 are cross sectional diagrams showing states partway through the manufacture of the semiconductor device according to Embodiment 1. FIGS. 2 to 11 show a cross sectional structure from one portion of the active region 27 to the edge termination structure portion 26 of one element among a plurality of elements fabricated on an n⁻ type wafer (hereafter, the same also applies to FIGS. 13 to 25). Firstly, the n⁻ type FZ wafer 1 made using, for example, a floating zone (FZ) method is prepared, as shown in FIG. 2.

Next, using a thermal oxidation method, a screen oxide film 21 of a thickness of, for example, 30 nm is formed on the front surface of the n⁻ type FZ wafer 1. Next, n-type impurity ions such as, for example, arsenic (As) ions or antimony (Sb) ions are implanted through the screen oxide film 21 into the front surface of the n⁻ type FZ wafer 1. This ion implantation conditions may be such that, for example, the dose is 1.0×10¹² cm⁻² to 3.0×10¹² cm⁻², and the acceleration energy 100 keV.

Next, a thermal annealing process (thermal diffusion process) is carried out for 30 minutes at a temperature of 900° C. in, for example, a nitrogen (N) atmosphere, thus forming the n-type field stop region 3 in a surface layer of the front surface of the n⁻ type FZ wafer 1, as shown in FIG. 3. Owing to the thermal annealing process for forming the n-type field stop region 3, it is possible to prevent the surface morphology of the n⁻ type FZ wafer 1 surface from deteriorating. Next, the screen oxide film 21 is removed.

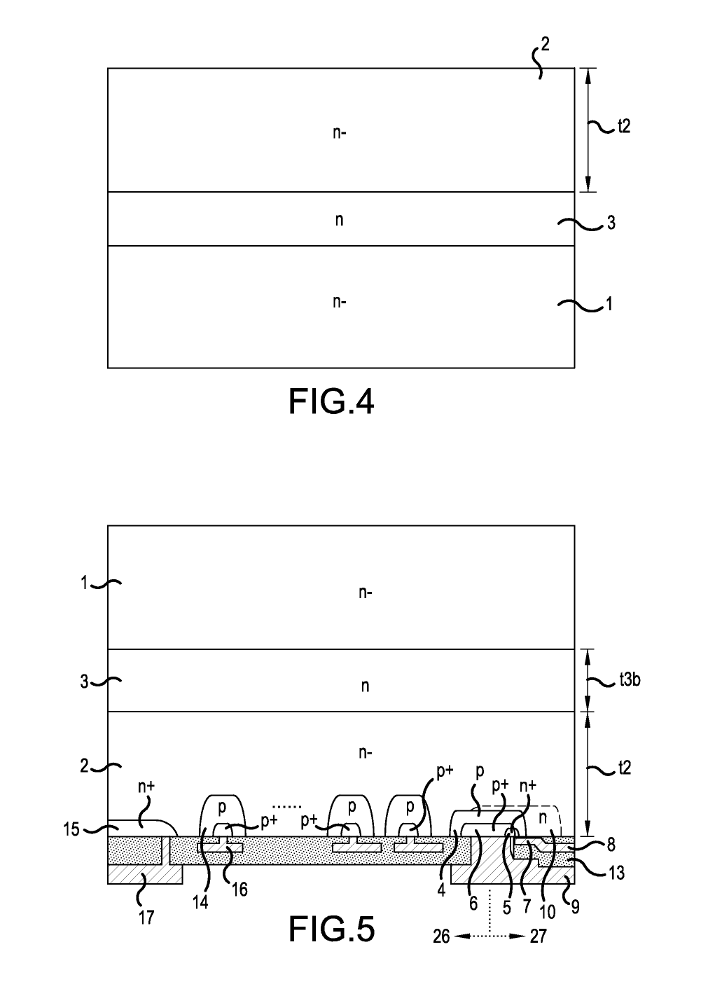

Next, an n⁻ type epitaxial layer doped with an n-type impurity such as, for example, phosphorus (P) is grown on the n-type field stop region 3, as shown in FIG. 4. The n⁻ type epitaxial layer forms the n⁻ type drift region 2. The n⁻ type drift region 2 is formed so that, for example, the thickness t2 is in the region of 45 μm, and resistivity is 13 Ω·cm to 20 Ω·cm.

By the n⁻ type drift region 2 being grown on the n-type field stop region 3, an n⁻ type wafer wherein the n⁻ type FZ wafer 1, the n-type field stop region 3, and the n⁻ type drift region 2 are stacked sequentially is fabricated. The n-type field stop region 3 is further thermally diffused (driven in) in the process of forming the n⁻ type drift region 2. Because of this, the diffusion depth of the n-type field stop region 3 is greater than before the formation of the n⁻ type drift region 2.

Next, by a general method, an FS-IGBT front surface element structure is formed on the front surface of the n⁻ type wafer (the surface of the n⁻ type drift region 2 on the side opposite to the n-type field stop region 3 side), as shown in FIG. 5. An FS-IGBT front surface element structure is an element structure formed of a MOS gate structure, an emitter electrode 9, in the active region 27, and an edge termination structure formed of the FLR 14, the n⁺ type region 15, and the FPs 16 and 17 in the edge termination structure portion 26. A MOS gate structure is formed of the p-type base region 4, the n⁺ type emitter region 5, the p⁺ type base contact region 6, the n-type hole barrier region 10, the gate dielectric 7, and the gate electrode 8.

The n-type field stop region 3 is further thermally diffused by the thermal budget (thermal history) for forming the FS-IGBT front surface element structure. Because of this, the thickness of the n-type field stop region 3 turns into, for example, the thickness t3b of the n-type field stop region 3 in the chip outer peripheral portion B after completion of the FS-IGBT. Although the n⁻ type wafer is shown with the front surface in a downward facing state in FIG. 5, the orientation of the main surfaces of the n⁻ type wafer can be variously changed in accordance with the manufacturing step.

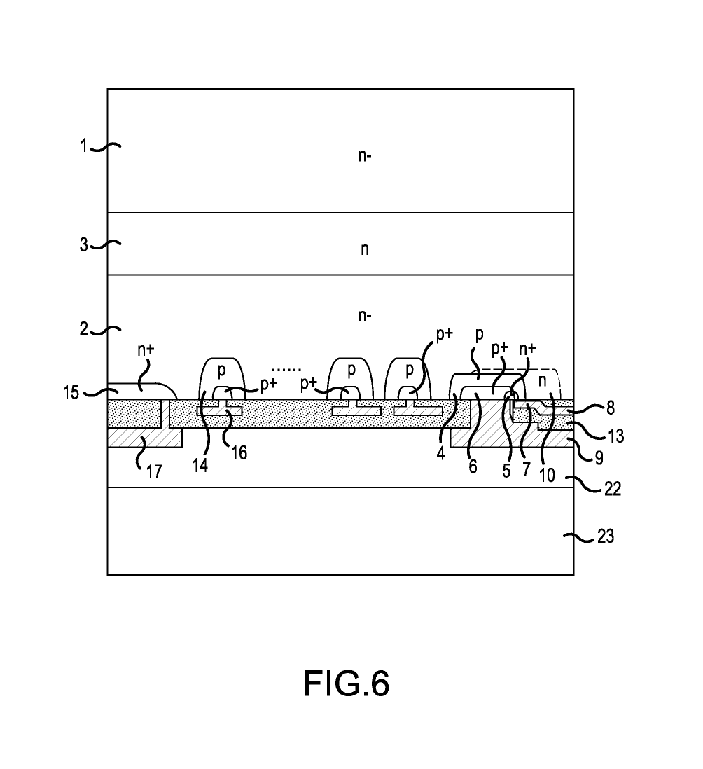

Next, a passivation layer (not shown) of a polyimide film or a nitride film is formed on the whole front surface of the n⁻ type wafer so as to cover the emitter electrode 9 and the FP 17. Next, the passivation layer is etched so that an FS-IGBT electrode region is exposed, thus forming electrode pads region (not shown). Next, a protective resist is applied to the whole of the front surface of the n⁻ type wafer, and a protective resist layer 22 that protects the FS-IGBT front surface element structure is formed by the protective resist being structure modified and cured, as shown in FIG. 6. Next, a back grinding tape (BG tape) 23 is attached to the front surface of the n⁻ type wafer covered by the protective resist layer 22.

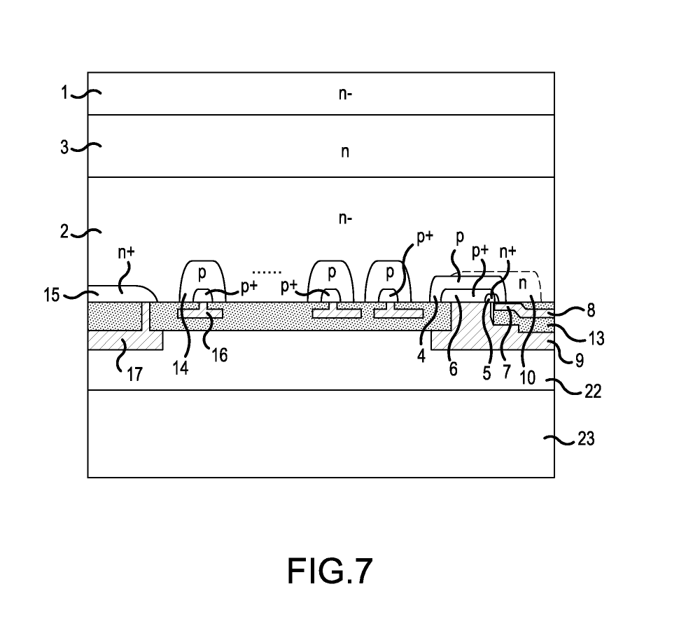

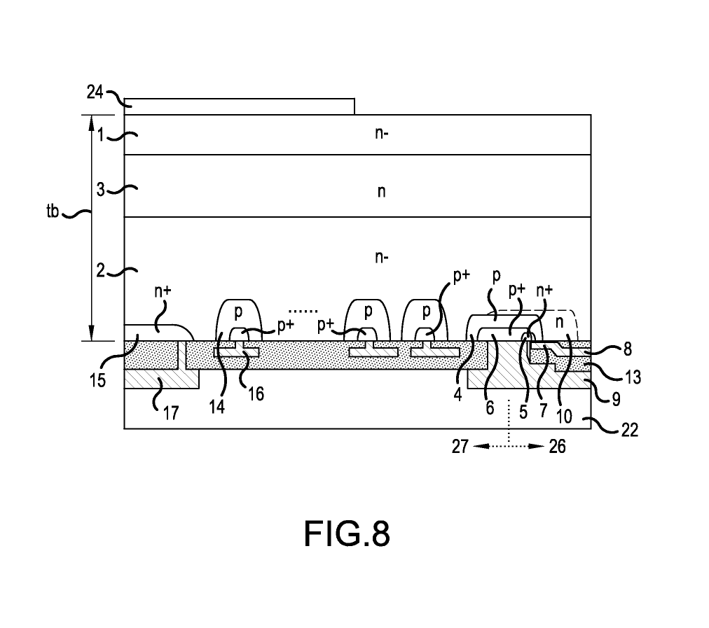

Next, the back surface of the n⁻ type wafer (back surface of the n⁻ type FZ wafer 1) is uniformly ground until the thickness of the n⁻ type wafer is approximately, for example, 120 μm, as shown in FIG. 7, followed by a mirror polish of the back surface of the n⁻ type wafer by touch polishing. Next, the BG tape 23 is removed, as shown in FIG. 8, and the n⁻ type wafer is cleaned. Next, the back surface of the n⁻ type wafer is etched, thus reducing the thickness of the n⁻ type wafer by, for example, 5 μm to 20 μm. Because of this, the thickness of the n⁻ type wafer is the thickness tb of the chip outer peripheral portion B after completion of the FS-IGBT. Next, a resist mask 24 having an aperture portion that exposes the back surface of the n⁻ type wafer from one portion of the edge termination structure portion 26 to the active region 27 is formed on the back surface of the n⁻ type wafer.

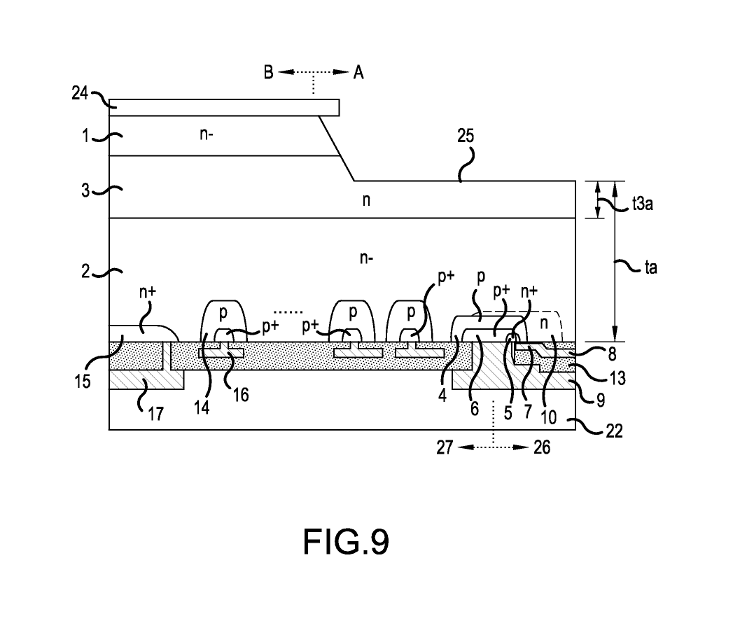

Next, for example, a wet anisotropic etching is carried out with the resist mask 24 as a mask, thus forming the groove 25 penetrating the n⁻ type FZ wafer 1 and reaching the n-type field stop region 3, as shown in FIG. 9. The cross sectional form of the groove 25 is, for example, a trapezium wherein the width of a bottom portion is less than the width on the opening side. The etchant for forming the groove 25 may have, for example, a tetramethylammonium hydroxide (TMAH) solution as a main component. Because of the groove 25, the n⁻ type FZ wafer 1 and n-type field stop region 3 are exposed on the back surface of the n⁻ type wafer.

Also, because of the groove 25, the thickness t3a of the portion of the n-type field stop region 3 exposed in the aperture portion of the resist mask 24 is 1.5 μm to 10.0 μm, which is less than the thickness t3b of the portion of the n-type field stop region 3 covered by the resist mask 24. The thickness of the portion of the n⁻ type wafer exposed in the aperture portion of the resist mask 24 is the thickness to of the chip inner portion A after completion of the FS-IGBT. Because of this, the chip inner portion A, whose thickness is less than that of the chip outer peripheral portion B, is formed in each region of the n⁻ type wafer that forms the n⁻ type chip after completion of the FS-IGBT.

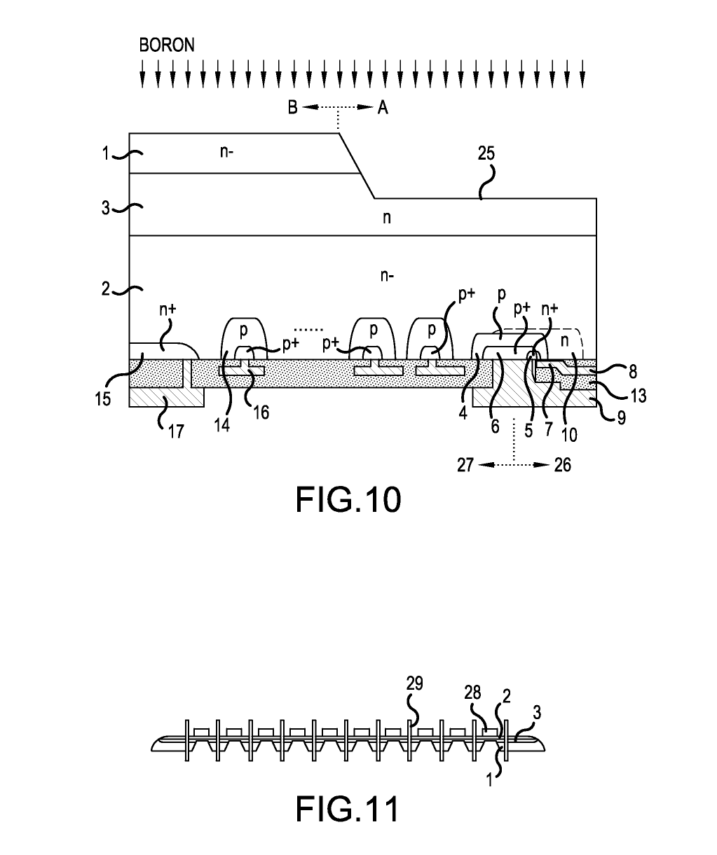

Next, the resist mask 24 is removed, and the back surface of the n⁻ type wafer is cleaned. Next, p-type impurity ions, such as boron (B) ions, are implanted into the whole back surface of the n⁻ type wafer, that is, into the surface of the n⁻ type FZ wafer 1 exposed on the back surface of the n⁻ type wafer and side walls of the groove 25 and into the surface of the n-type field stop region 3 exposed on the side walls and bottom surface of the groove 25, as shown in FIG. 10. The ion implantation conditions may be such that, for example, the dose is 5.0×10¹² cm⁻² to 1.5×10¹³ cm⁻², and the acceleration energy 30 keV to 60 keV.

Next, the p-type impurity ion implanted into the whole of the back surface of the n⁻ type wafer is activated by a laser annealing process, thereby forming the p-type collector region 11 in a surface layer of the n⁻ type FZ wafer 1 exposed on the back surface of the n⁻ type wafer and a surface layer of the n-type field stop region 3. The laser annealing process may be carried out at an energy density of 1.0 J/cm² to 2.0 J/cm² using, for example, a YAG laser with a wavelength of 532 nm. Next, the protective resist layer 22 formed on the front surface of the n⁻ type wafer is removed, after which a metal electrode material is deposited over the whole back surface of the n⁻ type wafer.

Next, an annealing process for the metal electrode material deposited over the whole of the back surface of the n⁻ type wafer is carried out at a temperature of 180° C. to 330° C. in, for example, in a hydrogen (H) containing atmosphere, thereby forming the collector electrode 12. The collector electrode 12 is formed so that the distance in the chip thickness direction between the collector electrode 12 and the n-type field stop region 3 is greater in the chip outer peripheral portion B than in the chip inner portion A after completion of the FS-IGBT (second distance x1b>first distance x1a). Subsequently, the n⁻ type wafer is diced along dicing lines 29, and singulated by cutting into individual chips on which an FS-IGBT front surface element structure 28 is formed, as shown in FIG. 11. By so doing, the FS-IGBT shown in FIG. 1 is completed.

As heretofore described, according to Embodiment 1, by an n⁻ type drift region being grown on the front surface of an n⁻ type FZ wafer in which an n-type field stop region is formed, and a groove being formed from the n⁻ type FZ wafer side in each region that forms an n⁻ type chip, it is possible for the thickness of the chip outer peripheral portion to be left greater than the thickness of the chip inner portion in each region that forms an n⁻ type chip. Because of this, it is possible to disperse the concentration of stress on the n⁻ type wafer, and thus possible to maintain the mechanical strength of the n⁻ type wafer. Also, by the thickness of the chip outer peripheral portion being left greater than the thickness of the chip inner portion, and the distance in the chip thickness direction between the collector electrode and the n-type field stop region being greater in the edge termination structure portion than in the active region, it is possible to reduce the amount of carriers injected from the p-type collector region in the edge termination structure portion compared with a semiconductor device wherein the chip thickness is uniform from the edge termination structure portion to the active region. Because of this, the destruction risk of the edge termination structure when a large current is turned off is markedly reduced, and the reverse biased safe operating area (RBSOA) of the device becomes easier to maintain.

Also, according to Embodiment 1, by a groove being formed in the back surface of the n⁻ type wafer (the surface on the n⁻ type FZ wafer side), leaving the thickness of the chip outer peripheral portion greater than the thickness of the chip inner portion in each region that forms an n⁻ type chip, it is possible to reduce the chip thickness in the active region compared with that in a heretofore known rib wafer wherein only the wafer outer peripheral portion is left thicker than the wafer inner portion. Also, by a deep groove reaching the n-type field stop region being formed from the back surface of the n⁻ type wafer, it is possible to further reduce the thickness of the chip inner portion. Because of this, when fabricating a low breakdown voltage IGBT of a breakdown voltage class of, for example, 600V or less, it is possible for the thickness of the n⁻ type drift region to be the ideal thickness demanded by the design in order to realize the required breakdown voltage. Consequently, it is possible to provide a semiconductor device and a semiconductor device manufacturing method that may have the optimum electrical characteristics obtainable from the design.

Also, according to Embodiment 1, by the thickness of the chip outer peripheral portion being left greater than the thickness of the chip inner portion in each region that forms an n⁻ type chip, the p-type collector region, the collector electrode, and the like, provided in the active region do not come into contact with a support stand on which the n⁻ type wafer is mounted during, for example, an electrical characteristic test carried out on the n⁻ type wafer before dicing. Because of this, it is possible to prevent a degradation in device breakdown voltage or an increase in leakage current, while for RB-IGBT, also a degradation in reverse breakdown voltage characteristics.

Also, according to Embodiment 1, it is possible to reduce the chip thickness in the active region to the ideal thickness demanded by the design in order to realize the required breakdown voltage, because of which it is possible to improve the trade-off relationship between device conduction loss and switching loss to reduce both the conduction loss and the switching loss.

### Embodiment 2

A description will be given of a semiconductor device according to Embodiment 2. FIG. 12 is a cross sectional diagram showing a configuration of the semiconductor device according to Embodiment 2. The semiconductor device according to Embodiment 2 differs from the semiconductor device according to Embodiment 1 in that a groove 35 provided in the back surface of the n⁻ type wafer is designed so as not to reach the n-type field stop region 3. That is, the p-type collector region 11 is in contact with only the n⁻ type FZ wafer 1 from the edge termination structure portion 26 to the active region 27.

A third distance x2a in the chip thickness direction between the p-type collector region 11 and n-type field stop region 3 in the chip inner portion A is less than a fourth distance x2b in the chip thickness direction between the p-type collector region 11 and the n-type field stop region 3 in the chip outer peripheral portion B. The third distance x2a may be an arbitrary thickness in accordance with etching process capability, but may be, for example, 1.0 μm or more. Because of this, it is possible to reduce the amount of carriers injected from the p-type collector region 11 into the n⁻ type drift region 2 in the edge termination structure portion 26 in an off-state compared with an FS-IGBT wherein the thickness of the n⁻ type chip is uniform from the edge termination structure portion 26 to the active region 27. Also, as the etching does not reach the n-type field stop region 3, it is possible to control the thickness and the impurity concentration of the n-type field stop region 3 more accurately than in Embodiment 1.

The third distance x2a is a thickness t1a of the n⁻ type FZ wafer 1 in the chip inner portion A. The fourth distance x2b is the thickness t1 of the n⁻ type FZ wafer 1 in the chip outer peripheral portion B. The thickness to of the chip inner portion A is a thickness that is the sum of the thickness t2 of the n⁻ type drift region 2, a thickness t3 of the n-type field stop region 3, the thickness t1a of the n⁻ type FZ wafer 1 in the chip inner portion A, and the thickness t11 of the p-type collector region 11. Configurations other than the groove 35 of the semiconductor device according to Embodiment 2 are the same as those of the semiconductor device according to Embodiment 1.

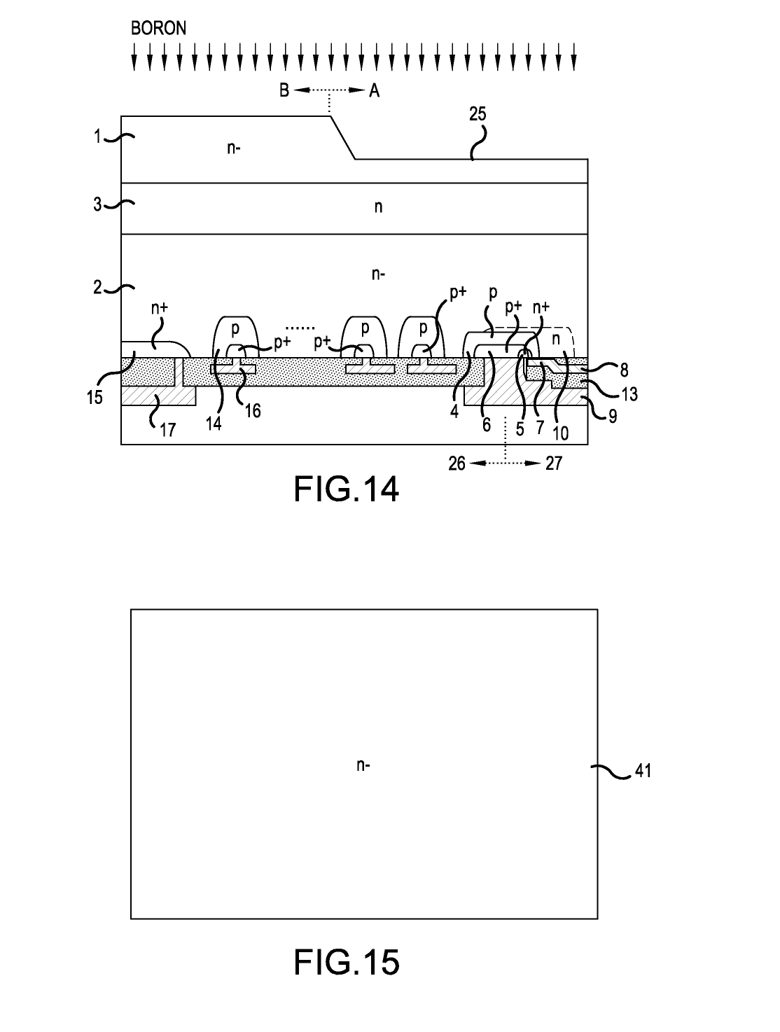

Next, a description will be given of a method of manufacturing the semiconductor device according to Embodiment 2, with a 400V breakdown voltage class FS-IGBT as an example. FIGS. 13 and 14 are cross sectional diagrams showing states partway through the manufacture of the semiconductor device according to Embodiment 2. Firstly, in the same way as in Embodiment 1, an n⁻ type wafer is fabricated, and steps from a step of forming an FS-IGBT front surface element structure to a step of reducing (thinning) the overall thickness of the n⁻ type wafer as far as the thickness tb of the chip outer peripheral portion B after completion of the FS-IGBT are carried out, as shown in FIGS. 2 to 8. However, the n-type field stop region 3 formation of FIG. 3 is such that the n-type field stop region 3, being formed to be thinner than in Embodiment 1, may be 1.5 μm to 3.0 μm after the step of FIG. 4.

Next, etching is carried out with the resist mask 24 as a mask, in the same way as in Embodiment 1, forming the groove 35 to a depth less than the thickness of the n⁻ type FZ wafer 1, as shown in FIG. 13. By so doing, the chip inner portion A, of a thickness less than that of the chip outer peripheral portion B, is formed in each region that forms an n⁻ type chip after completion of the FS-IGBT. Also, the thickness t1a of the n⁻ type FZ wafer 1 in the chip inner portion A is less than the thickness t1 of the n⁻ type FZ wafer 1 in the chip outer peripheral portion B. The etching conditions for forming the groove 35 are the same as those in Embodiment 1. Next, the resist mask 24 is removed, and the back surface of the n⁻ type wafer is cleaned.

Next, p-type impurity ions, such as boron ions, are implanted into the whole back surface of the n⁻ type wafer, that is, into the surface of the n⁻ type FZ wafer 1 exposed on the back surface of the n⁻ type wafer and side walls and bottom surface of the groove 35, as shown in FIG. 14. The ion implantation conditions are the same as those in Embodiment 1. Next, a laser annealing process is carried out over the whole back surface of the n⁻ type wafer, thereby forming the p-type collector region 11 in contact with the n⁻ type FZ wafer 1. The laser annealing process conditions are the same as those in Embodiment 1. Subsequently, in the same way as in Embodiment 1, the FS-IGBT shown in FIG. 12 is completed by the steps from the step of forming the collector electrode 12 onward.

As heretofore described, according to Embodiment 2, it is possible to obtain the same advantages as in Embodiment 1. Also, according to Embodiment 2, by forming a groove that does not reach the n-type field stop region in the back surface of the n⁻ type wafer, it is possible to reduce variation in the thickness of the n-type field stop region in the active region, and in the total dose of the n-type field stop region (a dose that is the dose of the n-type field stop region integrated in the thickness direction), caused by processing variation when forming the groove. Because of this, it is possible to increase control accuracy when forming the n-type field stop region. Consequently, it is possible to keep the element electrical characteristics within an allowable fluctuation range, and thus possible to reduce fluctuation in the field stop effect and the collector injection efficiency.

### Embodiment 3

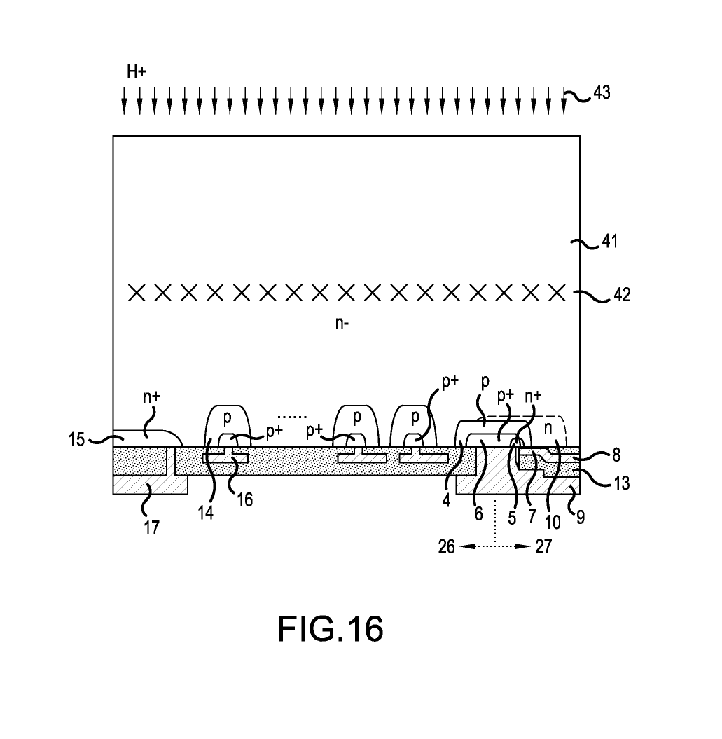

Next, a description will be given of a semiconductor device manufacturing method according to Embodiment 3, with an example case of fabricating a 400V breakdown voltage class FS-IGBT. FIGS. 15 and 16 are cross sectional diagrams showing states partway through the manufacture of the semiconductor device according to Embodiment 3. The semiconductor device manufacturing method according to Embodiment 3 differs from the semiconductor device manufacturing method according to Embodiment 1 in that an n⁻ type FZ wafer 41 thicker than that of Embodiment 1 is used, and that the n-type field stop region 3 is formed using a proton (H⁺) implantation 43 and a thermal annealing process for transforming the protons into donors.

Specifically, firstly, for example, the n⁻ type FZ wafer 41, of a thickness greater than the thickness tb of the chip outer peripheral portion B after completion of the FS-IGBT, is prepared, as shown in FIG. 15. Specifically, the thickness of the n⁻ type FZ wafer 41 may be approximately, for example, 500 μm. The resistivity of the n⁻ type FZ wafer 41 may be, for example, 13 Ω·cm to 20 Ω·cm. The diameter of the n⁻ type FZ wafer 41 may be, for example, 6 inches. Next, an FS-IGBT front surface element structure is formed on the front surface of the n⁻ type FZ wafer 41, as shown in FIG. 16. Next, in the same way as in Embodiment 1, a passivation layer (not shown) is formed on the front surface of the n⁻ type wafer, and the passivation layer is etched, thus to form electrode pad regions (not shown).

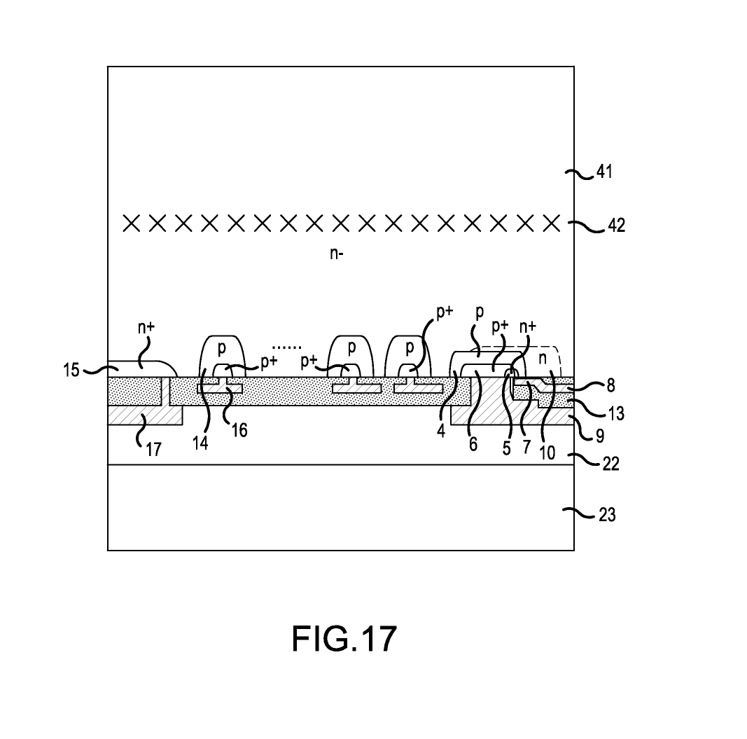

Next, protons are implanted from the back surface of the n⁻ type FZ wafer 41 (the proton implantation 43), thereby forming a region 42 having an impurity level in accordance with the protons at a predetermined depth in the n⁻ type FZ wafer 41 (shown by X in FIG. 16. The same also applies to FIGS. 17 to 21 and 25). The proton implantation 43 may be carried out so that the boundary of the n⁻ type drift region 2 and n-type field stop region 3 is positioned at a depth approximately 40 μm from the front surface of the n⁻ type FZ wafer 41. The conditions of proton implantation 43 may be such that, for example, the total proton dose at the predetermined depth in the n⁻ type FZ wafer 41 is 5.0×10¹³ cm⁻² to 5.0×10¹⁴ cm⁻², and the acceleration energy 7 MeV to 8 MeV. Also, the proton implantation 43, being carried out once or multiple times with acceleration energy within the heretofore described range, is carried out so that the total proton dose at the predetermined depth in the n⁻ type FZ wafer 41 is within the heretofore described range.

Next, a thermal annealing process is carried out for 30 minutes to 60 minutes at a temperature of 330° C. to 370° C. in, for example, a hydrogen containing atmosphere, thereby activating (transforming into donors) the protons formed inside the n⁻ type FZ wafer 1. By so doing, the n-type field stop region 3, formed by the protons being transformed into donors, is formed to a thickness of approximately 10 μm at a predetermined depth in the n⁻ type FZ wafer 41. Further, the n⁻ type FZ wafer 41 is divided by the n-type field stop region 3 and, in the same way as in Embodiment 1, two n⁻ type regions are formed so as to sandwich the n-type field stop region 3, as shown in FIG. 6. The average impurity concentration of the n-type field stop region 3 may be 1.0×10¹⁵ cm⁻³ to 1.0×10¹⁶ cm⁻³.

Of the two n⁻ type regions formed so as to sandwich the n-type field stop region 3, the n⁻ type region on which the FS-IGBT front surface element structure is formed is the n⁻ type drift region 2. Next, in the same way as in Embodiment 1, the protective resist layer 22 is formed over the whole front surface of the n⁻ type FZ wafer 41 and the BG tape 23 is attached, after which the FS-IGBT shown in FIG. 1 is completed by the steps from the step of thinning the n⁻ type FZ wafer 41 onward, as shown in FIGS. 6 to 11. In FIGS. 1 and 6 to 11, the n⁻ type FZ wafer 41 is indicated by reference sign 1 (hereafter, the same also applies to FIGS. 12 to 14).

Also, by forming the groove 35, in the same way as in Embodiment 2, instead of forming the groove 25, it is possible to fabricate the FS-IGBT shown in FIG. 12.

As heretofore described, according to Embodiment 3, it is possible to obtain the same advantages as in Embodiments 1 and 2. Also, according to Embodiment 3, the thermal annealing temperature necessary for activating the protons is low at around 350° C., because of which it is possible to prevent an adverse effect on a front surface element structure metal electrode formed before carrying out the thermal annealing process for activating the protons. Also, according to Embodiment 3, the n-type field stop region is formed by implanting protons into the n⁻ type FZ wafer before reducing the thickness of the n⁻ type FZ wafer overall or selectively, because of which it is possible to reduce the risk of the n⁻ type FZ wafer cracking. Also, according to Embodiment 3, the thermal annealing process for activating (transforming into donors) the protons is carried out at a timing differing from that of another thermal annealing process, because of which it is possible to carry out the thermal annealing process for activating the protons under conditions optimal for activating the protons.

Also, according to Embodiment 3, by the groove being formed so that the n⁻ type FZ wafer remains in the chip inner portion, the depth of silicon melting of the n⁻ type FZ wafer caused by laser annealing of the wafer back surface for forming the p-type collector region does not reach the n-type field stop region in the chip inner portion either. Because of this, it is possible to prevent complete crystallization of the n-type field stop region formed by protons being transformed into donors. Consequently, it is possible for the n-type field stop region to be of a desired n-type impurity concentration.

### Embodiment 4

A description will be given of a semiconductor device manufacturing method according to Embodiment 4, with an example of fabricating a 400V breakdown voltage class FS-IGBT. FIGS. 17 to 21 are cross sectional diagrams showing states partway through the manufacture of the semiconductor device according to Embodiment 4. The semiconductor device manufacturing method according to Embodiment 4 differs from the semiconductor device manufacturing method according to Embodiment 3 in that the p-type collector region 11 and n-type field stop region 3 are formed by a single thermal annealing process.

Specifically, firstly, in the same way as in Embodiment 3, the n⁻ type FZ wafer 41 is prepared, and the FS-IGBT front surface element structure formation steps and proton implantation 43 step are carried out sequentially, as shown in FIGS. 15 and 16. Next, the step of attaching the BG tape 23 to the front surface of the n⁻ type wafer covered by the protective resist layer 22, the n⁻ type FZ wafer 41 thinning step, the groove 25 formation step, and the p-type impurity ion implantation step for forming the p-type collector region 11 are carried out sequentially, as shown in FIGS. 17 to 21. The steps shown in FIGS. 17 to 21 are carried out using, for example, the same methods as for the same steps (FIGS. 6 to 10) in Embodiment 1.

Next, the protective resist layer 22 formed on the front surface of the n⁻ type wafer is removed, and the n⁻ type FZ wafer 41 is cleaned. Next, a thermal annealing process for activating the protons and p-type impurity implanted into the n⁻ type FZ wafer 41 is carried out. The thermal annealing process conditions are the same as, for example, those of the thermal annealing process carried out in order to activate the protons in Embodiment 3. The n-type field stop region 3 and p-type collector region 11 are formed simultaneously by this single thermal annealing process. Next, in the same way as in Embodiment 1, the FS-IGBT shown in FIG. 1 is completed by the steps from the step of forming the collector electrode 12 onward.

Also, by forming the groove 35, in the same way as in Embodiment 2, instead of forming the groove 25, it is possible to fabricate the FS-IGBT shown in FIG. 12.

As heretofore described, according to Embodiment 4, it is possible to obtain the same advantages as in Embodiment 3. Also, according to Embodiment 4, it is possible to form the p-type collector region and n-type field stop region by a single thermal annealing process, because of which it is possible to simplify the manufacturing process.

### Embodiment 5

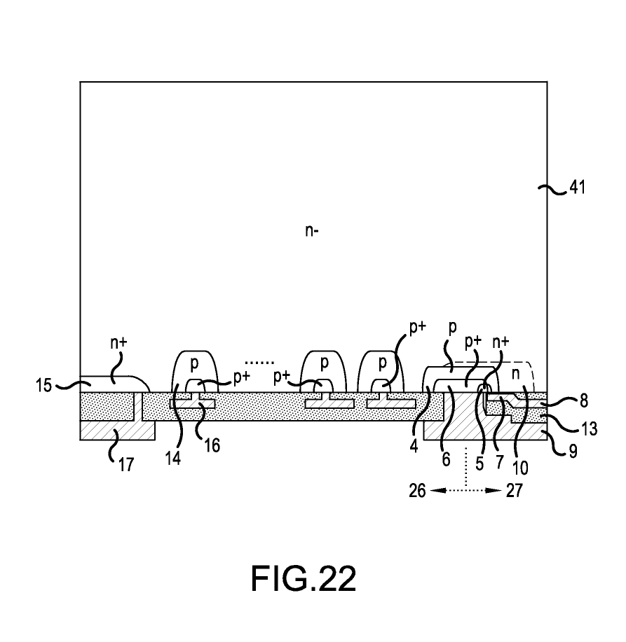

A description will be given of a semiconductor device manufacturing method according to Embodiment 5, with an example of fabricating a 400V breakdown voltage class FS-IGBT. FIGS. 22 to 25 are cross sectional diagrams showing states partway through the manufacture of the semiconductor device according to Embodiment 5. The semiconductor device manufacturing method according to Embodiment 5 differs from the semiconductor device manufacturing method according to Embodiment 4 in that a proton implantation 44 for forming the n-type field stop region 3 is carried out after the thinning of the n⁻ type FZ wafer 41.

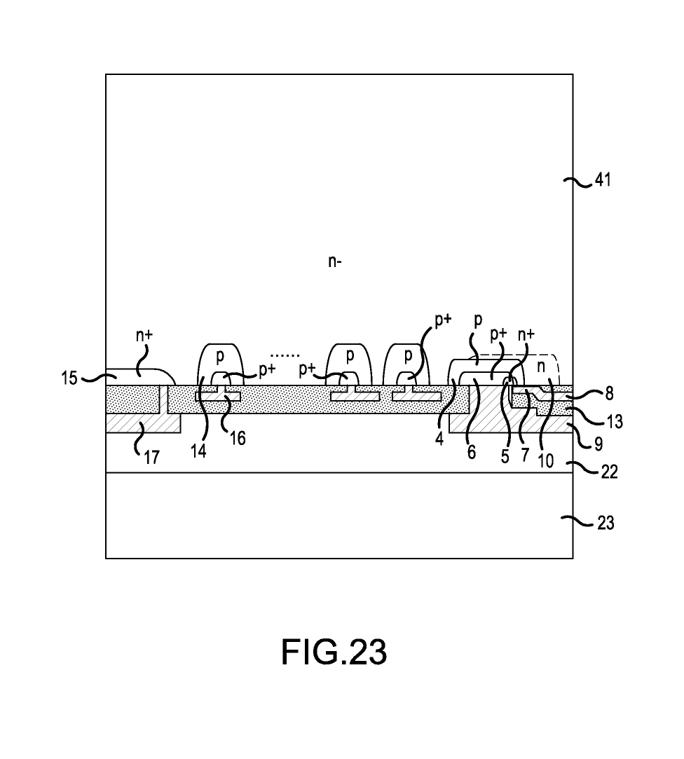

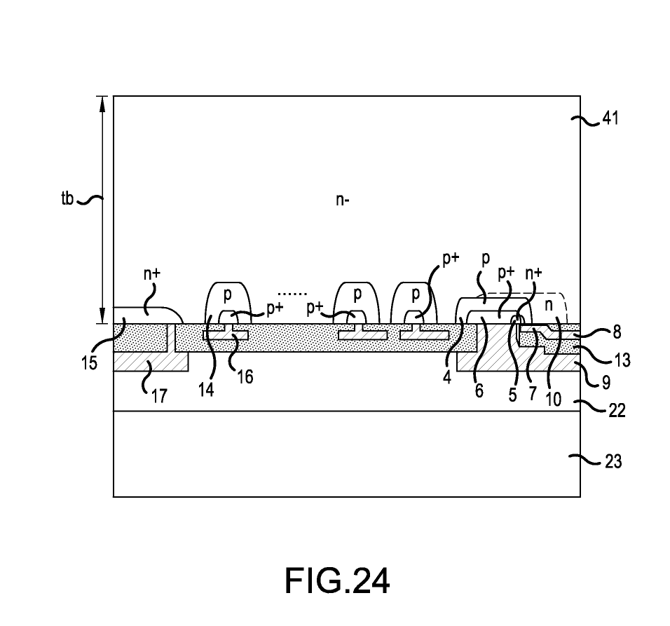

Specifically, firstly, in the same way as in Embodiment 3, the n⁻ type FZ wafer 41 is prepared, and the FS-IGBT front surface element structure is formed on the front surface of the n⁻ type FZ wafer 41, as shown in FIG. 22. Next, the protective resist layer 22 is formed over the whole front surface of the n⁻ type FZ wafer 41, and the BG tape 23 is attached to the front surface of the n⁻ type FZ wafer 41 covered by the protective resist layer 22, as shown in FIG. 23. Next, the n⁻ type FZ wafer 41 is thinned by grinding the back surface of the n⁻ type FZ wafer 41, as shown in FIG. 24. The steps shown in FIGS. 22 to 24 are carried out using, for example, the same methods as for the same steps (FIGS. 5 to 7) in Embodiment 1.

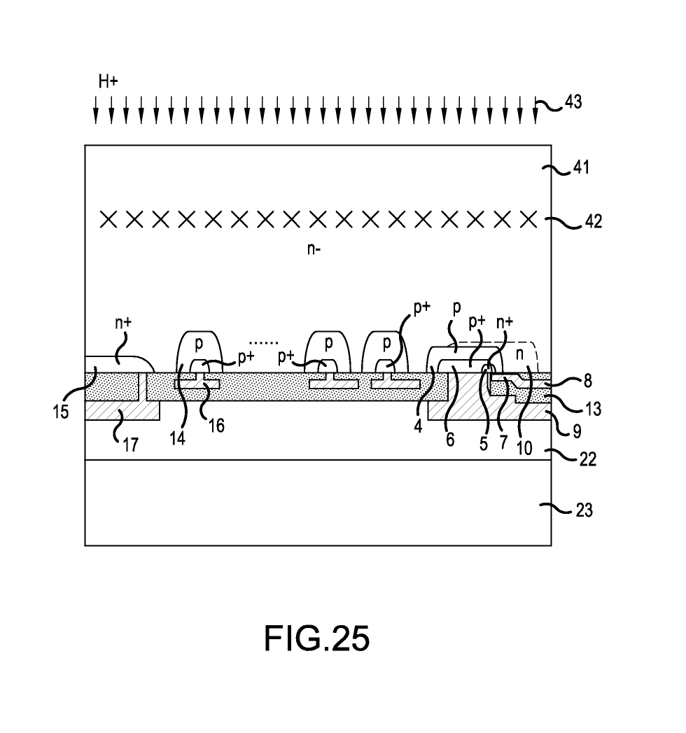

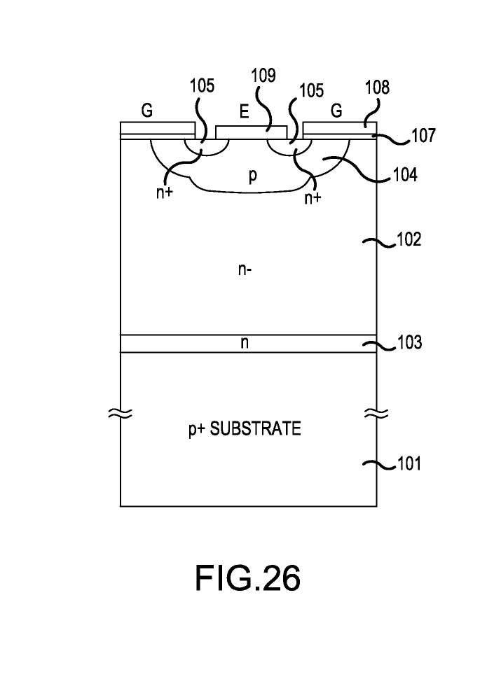

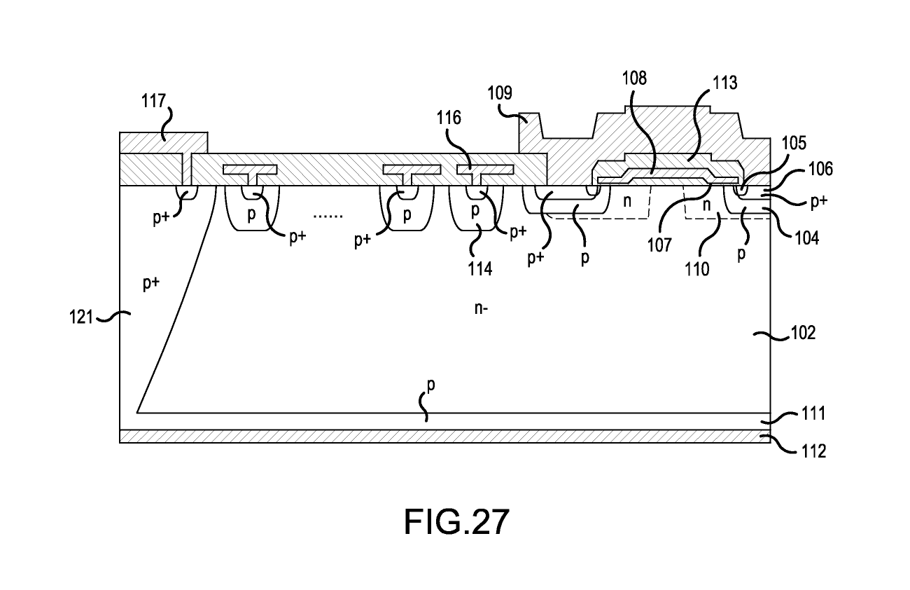

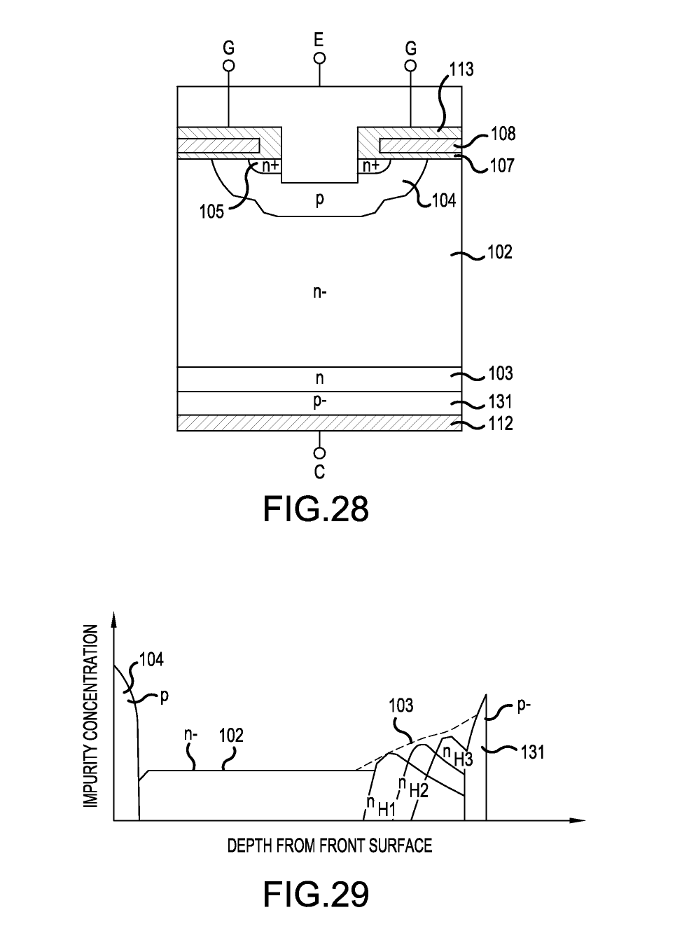

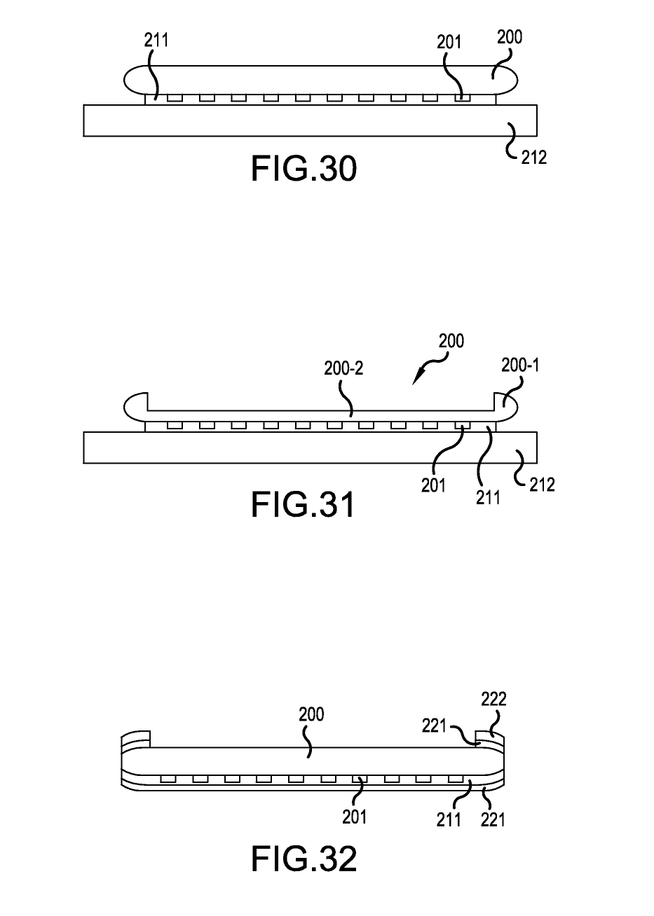

Next, protons are implanted from the back surface of the n⁻ type FZ wafer 41 (the proton implantation 44), thereby forming the region 42 having an impurity level in accordance with the protons at a predetermined depth in the n⁻ type FZ wafer 41, as shown in FIG. 25. The total dose of the protons implanted to the predetermined depth in the n⁻ type FZ wafer 41 by the proton implantation 44 is, for example, the same as in Embodiment 3. Also, the acceleration energy of the proton implantation 44 may be lower than that of the proton implantation 43 of Embodiment 3, for example, 1.6 MeV to 2.5 MeV.

The reason that the acceleration energy of the proton implantation 44 may be lower than the acceleration energy of the proton implantation 43 of Embodiment 3 is that the proton implantation 44 is carried out into the n⁻ type FZ wafer 41 which, because of the thinning, is thinner than the n⁻ type FZ wafer of the semiconductor device manufacturing method according to Embodiment 3. The proton implantation 44, being carried out once or multiple times with acceleration energy within the heretofore described range, is carried out so that the total proton dose at the predetermined depth in the n⁻ type FZ wafer 41 is within the heretofore described range. The thickness of the n-type field stop region 3 is approximately 3.0 μm. The average impurity concentration of the n-type field stop region 3 may be 1.0×10¹⁵ cm⁻³ to 1.0×10¹⁶ cm⁻³.

Next, in the same way as in Embodiment 4, the groove 25 formation step, the p-type impurity ion implantation step for forming the p-type collector region 11, and the thermal annealing process step for simultaneously activating the protons and p-type impurity implanted into the n⁻ type FZ wafer 41 are carried out, as shown in FIGS. 19 to 21. By so doing, the n-type field stop region 3 and p-type collector region 11 are formed. Subsequently, in the same way as in Embodiment 1, the FS-IGBT shown in FIG. 1 is completed by the steps from the step of forming the collector electrode 12 onward.

Also, by forming the groove 35, in the same way as in Embodiment 2, instead of forming the groove 25, it is possible to fabricate the FS-IGBT shown in FIG. 12.

As heretofore described, according to Embodiment 5, it is possible to obtain the same advantages as in Embodiments 3 and 4. Also, according to Embodiment 5, by carrying out a proton implantation into the n⁻ type FZ wafer after thinning, it is possible to reduce the acceleration energy of the proton implantation compared with when carrying out a proton implantation into the n⁻ type FZ wafer before thinning. Because of this, it is possible to reduce residual defects remaining inside the n⁻ type FZ wafer due to the proton implantation. Also, according to Embodiment 5, it is possible to carry out a proton implantation into the n⁻ type FZ wafer back surface after reducing undulations on the n⁻ type FZ wafer back surface by thinning. Because of this, it is possible to form the n-type field stop region to a uniform thickness.

### Embodiment 6

A description will be given of a semiconductor device manufacturing method according to Embodiment 6, with an example of fabricating a 400V breakdown voltage class FS-IGBT. The semiconductor device manufacturing method according to Embodiment 6 differs from the semiconductor device manufacturing method according to Embodiment 5 in that the thermal annealing process that activates the protons is carried out at a timing different from that of another thermal annealing process.

Specifically, the n⁻ type FZ wafer 41 is prepared and, in the same way as in Embodiment 5, the steps from the FS-IGBT front surface element structure formation steps to the p-type impurity ion implantation step for forming the p-type collector region 11 are carried out sequentially. Next, in the same way as in Embodiment 1, the p-type impurity ion implanted into the back surface of the n⁻ type FZ wafer 41 and side walls and bottom surface of the groove 25 is activated by a laser annealing process, thereby forming the p-type collector region 11.

Next, the protective resist layer 22 formed on the front surface of the n⁻ type FZ wafer 41 is removed, and the n⁻ type FZ wafer 41 is cleaned. Next, in the same way as in Embodiment 3, a thermal annealing process for activating the protons implanted into the n⁻ type FZ wafer 41 is carried out, thereby forming the n-type field stop region 3. Subsequently, in the same way as in Embodiment 1, the FS-IGBT shown in FIG. 1 is completed by the steps from the step of forming the collector electrode 12 onward.

Also, by forming the groove 35, in the same way as in Embodiment 2, instead of forming the groove 25, it is possible to fabricate the FS-IGBT shown in FIG. 12. Also, the semiconductor device manufacturing method according to Embodiment 6 may be applied to the semiconductor device manufacturing method according to Embodiment 4.

As heretofore described, according to Embodiment 6, it is possible to obtain the same advantages as in Embodiment 5. Also, according to Embodiment 6, the thermal annealing process that activates the protons is carried out at a timing different from that of another thermal annealing process, because of which it is possible to carry out the thermal annealing process for activating the protons under optimal conditions. Also, according to Embodiment 6, it is possible to reduce the thermal history remaining in the n⁻ type FZ wafer 41 by carrying out the thermal annealing process for activating the protons after the thinning of the n⁻ type FZ wafer 41. Because of this, it is possible to reduce warping of the n⁻ type FZ wafer 41 compared with when carrying out the thermal annealing process that activates the protons before the thinning of the n⁻ type FZ wafer 41. When forming the n-type field stop region using protons, it is possible to easily obtain a thickness of 3.0 μm to 10.0 μm.

The invention, not being limited to the heretofore described embodiments, is applicable to semiconductor devices with various device structures. Specifically, although a description has been given with a planar gate structure IGBT as an example in each embodiment, the invention may also be applied to, for example, a semiconductor device with a trench gate structure. Also, a first conductivity type is taken to be a p-type and a second conductivity type taken to be an n-type in each embodiment, but the invention is established in the same way when the first conductivity type is an n-type and the second conductivity type a p-type.

As heretofore described, the semiconductor device and a semiconductor device manufacturing method according to the invention are advantageous in a low breakdown voltage semiconductor device formed on a thinned wafer. Specifically, for example, the semiconductor device and semiconductor device manufacturing method according to the invention are useful in increasing the efficiency of a low breakdown voltage semiconductor device of a breakdown voltage class of 600V or less used in a pulse power supply of a PDP, a strobe, or the like, and of a commercial power converter with an AC input voltage of 200V. Furthermore, the semiconductor device and a semiconductor device manufacturing method according to the invention are useful in increasing the efficiency of an inverter that drives a motor in an electric vehicle.

1. A semiconductor device, comprising:
a first conductivity type chip comprising a first conductivity type first semiconductor region, a first conductivity type second semiconductor region, and a first conductivity type third semiconductor region provided between the first conductivity type first semiconductor region and the first conductivity type second semiconductor region and having a resistivity lower than that of the first conductivity type second semiconductor region;
a groove provided in the first conductivity type first semiconductor region;
an active region provided in an inner portion of the first conductivity type chip, a thickness of the inner portion being less than a thickness of an outer peripheral portion of the first conductivity type chip owing to the groove;
a termination structure portion provided in the outer peripheral portion of the first conductivity type chip, the termination structure portion configured to maintain a breakdown voltage;
a second conductivity type semiconductor region coupled with the first conductivity type first semiconductor region; and
an output electrode coupled with the second conductivity type semiconductor region,
wherein the distance in the first conductivity type chip thickness direction between the output electrode and the first conductivity type third semiconductor region is greater in the termination structure portion than in the active region.

2. The semiconductor device according to claim 1, wherein the groove penetrates the first conductivity type first semiconductor region and reaches the first conductivity type third semiconductor region.

3. The semiconductor device according to claim 1, wherein the groove is provided in the first conductivity type first semiconductor region to a depth less than the thickness of the first conductivity type first semiconductor region

4. The semiconductor device according to claim 3, wherein the thickness of the first conductivity type third semiconductor region is 1.5 μm or more or 10.0 μm or less.

5. The semiconductor device according to claim 2, wherein the average impurity concentration of the first conductivity type third semiconductor region is 3.0×10¹⁵ cm⁻³ to 2.0×10¹⁶ cm⁻³.

6. The semiconductor device according to claim 2, wherein the first conductivity type second semiconductor region is an epitaxial growth layer deposited on the first conductivity type third semiconductor region.

7. The semiconductor device according to claim 2, wherein the first conductivity type third semiconductor region is a region formed by protons introduced into the first conductivity type chip being transformed into donors.

8. The semiconductor device according to claim 2, wherein the resistivity of the first conductivity type second semiconductor region is equal to the resistivity of the first conductivity type first semiconductor region.

9. The semiconductor device according to claim 2, wherein the thickness of the outer peripheral portion of the first conductivity type chip is greater than 80 μm.

10. A method of manufacturing a semiconductor device including an edge termination structure portion that maintains breakdown voltage provided in an outer peripheral portion of a first conductivity type chip and an active region provided in an inner portion of the first conductivity type chip, the thickness of the inner portion being less than that of the outer peripheral portion,
the method comprising:
forming a first conductivity type semiconductor region having a resistivity lower than that of a first conductivity type wafer in the first conductivity type wafer;
forming a groove in the first conductivity type semiconductor region from the back surface of the first conductivity type wafer;
forming a second conductivity type semiconductor region on the back surface of the first conductivity type wafer and an inner wall of the groove; and
forming an output electrode on the second conductivity type semiconductor region,
wherein the distance in the first conductivity type wafer thickness direction to the first conductivity type semiconductor region is greater in the edge termination structure portion than in the active region.

11. The semiconductor device manufacturing method according to claim 10, wherein the groove reaches the first conductivity type semiconductor region.

12. The semiconductor device manufacturing method according to claim 10, wherein the groove is formed to a depth less than the thickness, in the first conductivity type wafer depth direction, from the back surface of the first conductivity type wafer to the first conductivity type semiconductor region;

13. The semiconductor device manufacturing method according to claim 10, wherein the first conductivity type wafer is formed by
forming the first conductivity type semiconductor region, having a resistivity lower than that of a first conductivity type support wafer, on a front surface of the first conductivity type support wafer, and
growing a first conductivity type epitaxial growth layer having a resistivity higher than that of the first conductivity type semiconductor region on the first conductivity type semiconductor region.

14. The semiconductor device manufacturing method according to claim 10, further comprising:
implanting protons from the back surface of the first conductivity type wafer, and
activating the protons implanted into the first conductivity type wafer using thermal annealing, thereby forming the first conductivity type semiconductor region in the first conductivity type wafer.

15. The semiconductor device manufacturing method according to claim 14, further comprising reducing the thickness of the first conductivity type wafer by grinding the back surface of the first conductivity type wafer before implanting the protons, wherein
the protons are implanted with an acceleration energy in a range of 1.6 MeV to 2.5 MeV, so that the total dose of the first conductivity type semiconductor region is in a range of 5.0×10¹³ cm⁻² to 5.0×10¹⁴ cm⁻².

16. The semiconductor device manufacturing method according to claim 14, further comprising reducing the thickness of the first conductivity type wafer by grinding the back surface of the first conductivity type wafer after implanting the protons, wherein
the protons are implanted with an acceleration energy in a range of 7.0 MeV to 8.0 MeV, so that the total dose of the first conductivity type semiconductor region is in a range of 5.0×10¹³ cm⁻² to 5.0×10¹⁴ cm⁻².

17. The semiconductor device manufacturing method according to claim 10, wherein the groove is formed by wet etching.

18-22. (canceled)
